(19) United States
(12) Patent Application Publication
(10) Pub. No.: US 2022/0154915 A1
(43) Pub. Date: May 19, 2022

(54) FLUORESCENT FILM AND CONVERSION LAYER

(71) Applicant: NEXDOT, Romainville (FR)

(72) Inventors: Michele D'AMICO, Romainville (FR); Alexis KUNTZMANN, Clichy La Garenne (FR); Yu-Pu LIN, Versailles (FR); Vladyslav VAKARIN, Palaiseau (FR)

(73) Assignee: NEXDOT, Romainville (FR)

(21) Appl. No.: 17/592,131

(22) Filed: Feb. 3, 2022

Related U.S. Application Data
(63) Continuation-in-part of application No. PCT/EP2020/071653, filed on Jul. 31, 2020.

(30) Foreign Application Priority Data
Aug. 5, 2019 (EP) 19190097.6

(51) Int. Cl. F21V 9/32; C09K 11/88; C09K 11/56

(52) U.S. Cl. CPC F21V 9/32; F21Y 2115/10; C09K 11/565; C09K 11/883

(57) ABSTRACT

A fluorescent film including a substrate and semiconductor nanoparticles distributed on the substrate according to a periodic pattern. The semiconductor nanoparticles have a longest dimension greater than 25 nanometers or an aspect ratio greater than 1.5, and the repetition unit of the pattern has a smallest dimension of less than 500 micrometers and comprises at least two pixels. Also, a process of manufacturing the fluorescent film.

### FIELD

The present invention pertains to the field of fluorescent materials. In particular, the invention relates to a fluorescent film, a process to prepare a fluorescent film and a colour conversion layer using fluorescent film.

### BACKGROUND

To represent colours in all their variety, one proceeds typically by additive synthesis of at least three complementary colours, especially red, green and blue. In a chromaticity diagram, the subset of available colours obtained by mixing different proportions of these three colours is formed by the triangle formed by the three coordinates associated with the three colours red, green and blue. This subset constitutes what is called a gamut.

A display device has to present the widest possible gamut for an accurate colour reproduction. For this, the composing sub-pixels must be of the most saturated colours possible in order to describe the widest possible gamut. A light source has a saturated colour if it is close to a monochromatic colour. From a spectral point of view, this means that light emitted by the source is comprised of a single luminescence narrow band. A highly saturated shade has a vivid, intense colour while a less saturated shade appears rather bland and gray.

It is therefore important to have light sources whose emission spectra are narrow and with saturated colours.

Usually, display devices use different sources for the three elementary colours. With the development of light-emitting diodes (LEDs) technologies, another design for display devices is spreading: a primary light source (LED) is used for the most energetic colour (usually blue). Then a conversion layer using fluorescence phenomena is laid over the primary light source. Conversion layer absorbs primary light and emits secondary light with a colour shift, i.e. red or green light. Thus, three colours are generated in the display device.

Various fluorescent materials, also known as phosphors may be used for conversion layer. Usual phosphors have fluorescence spectrum with a rather large full width half maximum, typically larger than 70 nm. This results in poor colour purity, leading to non-saturated colours and energy loss in the final display devices. In order to improve colour purity, narrow band filters may be used to select only the central part of fluorescence, but this leads to a huge loss of energy.

Semiconductor nanoparticles, commonly called “quantum dots”, are known as fluorescent material. Said objects have a narrow fluorescence spectrum, approximately 30 nm full width at half maximum, and offer the possibility to emit in the entire visible spectrum as well as in infrared range after optical excitation. Such nanoparticles can absorb light from the primary light source then eventually relax by emission of light of lower energy, i.e. with a colour shift.

It is known to use nanoplatelets to obtain great spectral emission finesse and a perfect control of the emission wavelength (see WO2013/140083).

Document US 2019/040,313 discloses fluorescent films comprising composite particles encapsulating semiconductor nanoplatelets in an inorganic material. US 2019/040,313 does not disclose a density of composite particles per cm² to allow a satisfying conversion ratio.

Document U.S. Pat. No. 9,975,764 discloses films comprising latex particles deposited on an electret substrate. Said films are not fluorescent films.

However, distributing such semiconductor nanoparticles on a periodic pattern with well controlled size, i.e. size of nanoparticles deposit and/or size of pattern, is still an unmet challenge.

It is therefore an object of the present invention to provide a fluorescent film having well controlled periodic pattern, which can be used as elementary brick for various light emitting devices, like display devices.

### SUMMARY

This invention thus relates to a fluorescent film comprising a substrate and semiconductor nanoparticles distributed on the substrate according to a periodic pattern, wherein semiconductor nanoparticles have at least one of:
a longest dimension greater than 25 nanometers; or
an aspect ratio greater than 1.5;

wherein the repetition unit of the pattern has a smallest dimension of less than 500 micrometers and comprises at least two pixels.

According to an embodiment, at least one pixel comprises a density of semiconductor nanoparticles per surface unit greater than 5×10⁹ nanoparticles·cm⁻² According to an embodiment, the pattern is periodic in two dimensions, preferably the periodic pattern is rectangular lattice or square lattice.

According to an embodiment, semiconductor nanoparticles are inorganic, preferably semiconductor nanoparticles are semiconductor nanocrystals comprising a material of formula MₓQ_{y}E_{z}A_{w}, wherein: M is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs; Q is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs; E is selected from the group consisting of O, S, Se, Te, C, N, P, As, Sb, F, Cl, Br, I; A is selected from the group consisting of O, S, Se, Te, C, N, P, As, Sb, F, Cl, Br, I; and x, y, z and w are independently a rational number from 0 to 5; x, y, z and w are not simultaneously equal to 0; x and y are not simultaneously equal to 0; z and w are not simultaneously equal to 0.

According to an embodiment, semiconductor nanoparticles have an aspect ratio greater than 1.5, preferably 3. In a particular configuration of this embodiment, semiconductor nanoparticles are on the substrate with their longest dimension substantially aligned in a predetermined direction.

According to an embodiment, semiconductor nanoparticles have a longest dimension greater than 25 nanometers and an aspect ratio greater than 1.5.

According to an embodiment, semiconductor nanoparticles are on two of the at least two pixels and semiconductor nanoparticles on the first pixel of the at least two pixels are different from semiconductor nanoparticles on the second pixel of the at least two pixels.

According to an embodiment, substrate comprises a primary light emitter, preferably a LED, more preferably a blue LED.

According to an embodiment, semiconductor nanoparticles are deposited with a thickness of less than 10000 nm and more than 100 nm, preferably less than 3000 nm and more than 200 nm.

According to an embodiment, semiconductor nanoparticles are composite nanoparticles comprising fluorescent semiconductor nanoparticles encapsulated in a matrix, preferably an inorganic matrix.

The invention also relates to a first process for the manufacture of a fluorescent film comprising a substrate and semiconductor nanoparticles distributed on the substrate according to a periodic pattern, wherein the repetition unit of the pattern has a smallest dimension of less than 500 micrometers and comprises at least two pixels comprising the steps of:
i) Providing an electret substrate;
ii) Writing a surface electric potential on the electret substrate according to the pattern, so that at least one pixel of the repetition unit is written in the whole pattern; and
iii) Bringing the electret substrate in contact for a contacting time of less than 15 minutes with a colloidal dispersion of semiconductor nanoparticles having at least one of a longest dimension greater than 25 nanometers or an aspect ratio greater than 1.5.

The invention also relates to a second process for the manufacture of a fluorescent film comprising a substrate and semiconductor nanoparticles distributed on the substrate according to a periodic pattern, wherein the repetition unit of the pattern has a smallest dimension of less than 500 micrometers and comprises at least two pixels and wherein semiconductor nanoparticles on the first pixel of the at least two pixels are different from semiconductor nanoparticles on the second pixel of the at least two pixels comprising the steps of:
i) Providing an electret substrate;
ii) Writing a surface electric potential on the electret substrate according to the pattern, so that the first pixel of the repetition unit is written in the whole pattern;
iii) Bringing the electret substrate in contact for a contacting time of less than 15 minutes with a colloidal dispersion of semiconductor nanoparticles having at least one of a longest dimension greater than 25 nanometers or an aspect ratio greater than 1.5;
iv) Drying the electret substrate and semiconductor nanoparticles deposited thereon to form an intermediate structure;
v) Writing a surface electric potential on the intermediate structure according to the pattern, so that the second pixel of the repetition unit is written in the whole pattern; and
vi) Bringing the electret substrate in contact for a contacting time of less than 15 minutes with a colloidal dispersion of semiconductor nanoparticles having at least one of a longest dimension greater than 25 nanometers or an aspect ratio greater than 1.5; and different from those used in step iii).

The invention also relates to a third process for the manufacture of a fluorescent film comprising a substrate and semiconductor nanoparticles distributed on the substrate according to a periodic pattern, wherein the repetition unit of the pattern has a smallest dimension of less than 500 micrometer and comprises at least two pixels comprising the steps of:
i) Providing a substrate;
ii) Inducing a surface electric potential on the substrate according to the pattern, so that at least one pixel of the repetition unit is induced in the whole pattern; and
iii) Bringing the substrate in contact for a contacting time of less than 15 minutes with a colloidal dispersion of semiconductor nanoparticles having at least one of a longest dimension greater than 25 nanometers or an aspect ratio greater than 1.5, while surface electric potential is maintained.

The invention also relates to a fourth process for the manufacture of a fluorescent film comprising a substrate and semiconductor nanoparticles distributed on the substrate according to a periodic pattern, wherein the repetition unit of the pattern has a smallest dimension of less than 500 micrometers and comprises at least two pixels and wherein semiconductor nanoparticles on the first pixel of the at least two pixels are different from semiconductor nanoparticles on the second pixel of the at least two pixels comprising the steps of:
i) Providing a substrate;
ii) Inducing a surface electric potential on the substrate according to the pattern, so that the first pixel of the repetition unit is induced in the whole pattern;
iii) Bringing the substrate in contact for a contacting time of less than 15 minutes with a colloidal dispersion of semiconductor nanoparticles having at least one of a longest dimension greater than 25 nanometers or an aspect ratio greater than 1.5, while surface electric potential is maintained;
iv) Drying the substrate and semiconductor nanoparticles deposited thereon to form an intermediate structure;
v) Inducing a surface electric potential on the intermediate structure according to the pattern, so that the second pixel of the repetition unit is induced in the whole pattern; and
vi) Bringing the substrate in contact for a contacting time of less than 15 minutes with a colloidal dispersion of semiconductor nanoparticles having at least one of a longest dimension greater than 25 nanometers or an aspect ratio greater than 1.5; and different from those used in step iii), while surface electric potential is maintained.

The invention further relates to a colour conversion layer comprising a fluorescent film comprising a substrate and semiconductor nanoparticles distributed on the substrate according to a periodic pattern, wherein semiconductor nanoparticles have at least one of a longest dimension greater than 25 nanometers or an aspect ratio greater than 1.5; wherein the repetition unit of the pattern has a smallest dimension of less than 500 micrometers and comprises at least two pixels.

### BRIEF DESCRIPTION OF THE DRAWINGS

FIG. 1 illustrates a schematic of a fluorescent film (1) comprising a substrate (2). A periodic pattern (here a square lattice) is shown as a network of dotted lines. At each node of the network, a repetition unit (3) of rectangular shape is shown. Smallest size of repetition unit is noted S. In repetition unit are shown three pixel of square section (4a), (4b—dotted line) and (4c). Semiconductor nanoparticles (not shown) are on the substrate (2), in the volume of pixel (4a) and (4c). Pixel (4b) is an area where primary light is emitted directly by primary light source without going through the fluorescent film: there are no nanoparticles in this pixel.

FIG. 2 illustrates an anisotropic nanoparticle, here a nanoplatelet, and defines aspect ratio.

FIG. 3 illustrates an aggregate of fluorescent semiconductor nanoparticles (10), here nanoplatelets, encapsulated in a matrix (20).

FIG. 4 shows emission spectrum (arbitrary unit) of nanoplatelets used in example 1 (emitting in red range: dashed line and green range: dotted line) as a function of light wavelength (λ in nanometer).

### DETAILED DESCRIPTION

In the present invention, the following terms have the following meanings:
“aspect ratio” is a feature of anisotropic particles. An anisotropic particle has three characteristic dimensions, one of which is the longest and one of which is the shortest.

Aspect ratio of an anisotropic particle is the ratio of the longest dimension divided by the shortest dimension. Aspect ratio is necessarily greater than 1. For instance, a nanoparticle of length L=30 nm, width W=20 nm and thickness T=10 nm has an aspect ratio of L/T=3, as shown on FIG. 2. Shape factor is a synonym of aspect ratio.
“blue range” refers to the range of wavelengths from 400 nm to 500 nm.
“colloidal” refers to a substance in which particles are dispersed, suspended and do not settle, flocculate or aggregate; or would take a very long time to settle appreciably, but are not soluble in said substance.
“colloidal nanoparticles” refers to nanoparticles that may be dispersed, suspended and which would not settle, flocculate or aggregate; or would take a very long time to settle appreciably in another substance, typically in an aqueous or organic solvent, and which are not soluble in said substance. “Colloidal nanoparticles” does not refer to particles grown on substrate.
“conversion ratio” refers to the ratio of energy emitted by the pixel divided by the energy provided to the pixel, i.e. to the ratio of photons emitted by the pixel divided by the photons provided to the pixel
“core/shell” refers to heterogeneous nanostructure comprising an inner part: the core, overcoated on its surface, totally or partially, by a film or a layer of at least one atom thick material different from the core: the shell. Core/shell structures are noted as follows: core material/shell material. For instance, a particle comprising a core of CdSe and a shell of ZnS is noted CdSe/ZnS. By extension, core/shell/shell structures are defined as core/first-shell structures overcoated on their surface, totally or partially, by a film or a layer of at least one atom thick material different from the core and/or from the first shell: the second-shell. For instance, a particle comprising a core of CdSe_{0.45}S_{0.55}, a first-shell of Cd_{0.80}Zn_{0.20}S and a second-shell of ZnS is noted CdSe_{0.45}S_{0.55}/Cd_{0.80}Zn_{0.20}S/ZnS.
“display device” refers to a device that displays an image signal. Display devices include all devices that display an image such as, non-limitatively, a television, a computer monitor, a personal digital assistant, a mobile phone, a laptop computer, a tablet PC, a tablet phone, a foldable tablet phone, an MP3 player, a CD player, a DVD player, a Blu-Ray player, a projector, a head mounted display, a smart watch, a watch phone or a smart device.
“encapsulate” refers to a material that coats, surrounds, embeds, contains, comprises, wraps, packs, or encloses a plurality of nanoparticles. Nanoparticles are encapsulated in said material.
“electret” refers to a material able to have a non-zero polarization density (i.e. the material contains electric dipole moments) for a long time, without external electric field. Polarization density may be created by injection of electric charges in material, said charges creating polarization density. In an electret material, dissipation of polarization density is slow (as compared to conductive materials), typically from tens of seconds to tens of minutes. To the purpose of the invention, the stability of polarization should be bigger than 1 minute.
“fluorescent” refers to the property of a material that emits light after being excited by absorption of light. Actually, light absorption drives said material in an excited state, which eventually relaxes by emission of light of lower energy, i.e. of longer wavelength.
“FWHM” refers to Full Width at Half Maximum for a band of emission/absorption of light.
“green range” refers to the range of wavelengths from 500 nm to 600 nm.
“MₓE_{z}” refers to a material composed of chemical element M and chemical element E, with a stoichiometry of x elements of M for z elements of E, x and z being independently a decimal number from 0 to 5; x and z not being simultaneously equal to 0. The stoichiometry of MₓE_{z} is not strictly limited to x:z but includes slight variations in composition due to nanometric size of nanoparticles, crystalline face effect and potentially doping. Actually, MₓE_{z} defines material with M content in atomic composition between x−5% and x+5%; with E content in atomic composition between z−5% and z+5%; and with atomic composition of compounds different from M or E from 0.001% to 5%. Same principle applies for materials composed of three of four chemical elements.
“nanoparticle” refers to a particle having at least one dimension in the 0.1 to 100 nanometers range. Nanoparticles may have any shape. A nanoparticle may be a single particle or an aggregate of several single particles or a composite particle comprising single particles dispersed in a matrix. Single particles may be crystalline. Single particles may have a core/shell or plate/crown structure.
“nanoplatelet” refers to a nanoparticle having a 2D-shape, i.e. having one dimension smaller than the two others; said smaller dimension ranging from 0.1 to 100 nanometers. In the sense of the present invention, the smallest dimension (hereafter referred to as the thickness) is smaller than the other two dimensions (hereafter referred to as the length and the width) by a factor (aspect ratio) of at least 1.5.
“optically transparent” refers to a material that absorbs less than 10%, 5%, 1%, or 0.5% of light at wavelengths between 200 nm and 2500 nm, between 200 nm and 2000 nm, between 200 nm and 1500 nm, between 200 nm and 1000 nm, between 200 nm and 800 nm, between 400 nm and 700 nm, between 400 nm and 600 nm, or between 400 nm and 470 nm.
“periodic pattern” refers to an organization of a surface on which a geometric element is repeated regularly, the length of repetition being the period. Lattices are specific periodic patterns.
“pixel” refers to a geometrical area in a repetition unit. By extension, if nanoparticles are on said area and form a volume of material: this volume is also a pixel. In particular, a pixel may be a sub-unit of a repetition unit.
“primary light source” refers to light source directed on nanoparticles to be absorbed by nanoparticles, the latter relaxing and emitting light of lower energy. In particular, primary light source is one of the three colours required for a display device, usually in blue range.
“red range” refers to the range of wavelengths from 600 nm to 720 nm.
“repetition unit” refers to a single geometric element that is repeated in a periodic pattern.

The following detailed description will be better understood when read in conjunction with the drawings. For the purpose of illustrating, the fluorescent film is shown in the preferred embodiments. It should be understood, however that the application is not limited to the precise arrangements, structures, features, embodiments, and aspect shown. The drawings are not drawn to scale and are not intended to limit the scope of the claims to the embodiments depicted. Accordingly, it should be understood that where features mentioned in the appended claims are followed by reference signs, such signs are included solely for the purpose of enhancing the intelligibility of the claims and are in no way limiting on the scope of the claims.

This invention relates to a fluorescent film comprising a substrate and semiconductor nanoparticles distributed on the substrate according to a periodic pattern. The repetition unit of the pattern has a smallest dimension of less than 500 micrometer. In some embodiments, the smallest dimension of the repetition unit of the pattern is less than 300 micrometer, less than 200 micrometer, less than 100 micrometer, less than 80 micrometer, less than 50 micrometer, less than 40 micrometer, less than 30 micrometer. Preferably, the smallest dimension of the repetition unit is greater than 3 micrometer, preferably greater than 5 micrometer, more preferably greater than 10 micrometer. Indeed, pixel size should be large enough to avoid diffraction or scattering of light emitted by the semiconductor nanoparticles that constitute pixels.

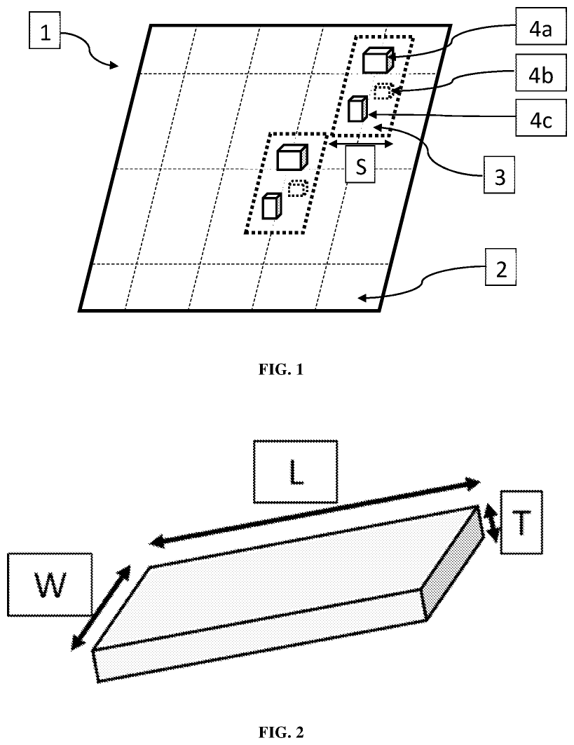

FIG. 1 illustrates an embodiment of the fluorescent film of the invention.

According to an embodiment, a pixel comprises a density of semiconductor nanoparticles per surface unit greater than 5×10⁹ nanoparticles·cm⁻², preferably greater than 7×10⁹ nanoparticles·cm⁻², more preferably greater than 5×10¹⁰ nanoparticles·cm⁻², most preferably greater than 5×10¹¹ nanoparticles·cm⁻². The density of semiconductor nanoparticles per surface unit in a pixel refers to the number of semiconductor nanoparticles per volume unit in a pixel multiplied by the thickness of the layer of semiconductor nanoparticles on said pixel. A high density of semiconductor nanoparticles is preferred also because the film is more uniform, compact and without cracks. A high density of semiconductor nanoparticles is also preferred as it allows a high conversion ratio, in particular a conversion ratio higher than 5%, preferably higher than 10%, more preferably higher than 20%. The conversion ratio depends on the absorption cross section of semiconductor nanoparticles, the thickness of the deposit of semiconductor nanoparticles and the quantum yield. Preferably, semiconductor have high absorption cross section and quantum yield, and the deposit have a thickness greater than 100 nm. In a preferred configuration of this embodiment, semiconductor nanoparticles are semiconductor nanoplatelets rather than quantum dots because the absorption cross section of nanoplatelets is higher than of quantum dots.

In another embodiment, a pixel comprises at least 3×10¹⁴ nanoparticles·cm⁻³, preferably at least 5×10¹⁴ nanoparticles·cm⁻³, more preferably at least 5×10¹⁵ nanoparticles·cm⁻³, most preferably at least 1×10¹⁷ nanoparticles·cm⁻³.

In this embodiment, the volume fraction of semiconductor nanoparticles in a pixel is ranging from 10% to 90%, preferably from 20% to 90%, more preferably from 30% to 90%, most preferably from 50% to 90%.

According to an embodiment, semiconductor nanoparticles are deposited with a thickness of less than 10000 nm and more than 100 nm, preferably less than 3000 nm and more than 200 nm.

In the invention, substrate may be an electret material. Alternatively, substrate may be covered by a layer, preferably said layer is an electret material.

Suitable electret material may be selected from polymers, for example: Fluorinated Ethylene Propylene (FEP), Polytetrafluoroethylene (PTFE), Polyethylene (PE), Polycarbonate (PC), Polypropylene (PP), Poly Vinylchloride (PVC), Polyethylene Terephtalate (PET), Polyimide (PI), Polymethyl Methacrylate (PMMA), Polyvinyl fluoride (PVF), Polyvinylidene Fluoride (PVDF), Polydimethylsiloxane (PDMS), Ethylene Vinyl Acetate (EVA), Cyclic Olefin Copolymers (COC), Polyparaxylylene (PPX), Fluorinated parylenes and fluorinated polymers in amorphous form.

Other suitable electret materials may be selected from inorganic materials, for example: Silicon Oxide (SiO₂), Silicon Nitride (Si₃N₄), Aluminium oxide (Al₂O₃) or other doped mineral glass with known dopant atoms (as example Na, S, Se, B).

For instance, a layer of Silicon, optionally doped, with a thin layer of 100 nm of polymethylmethacrylate polymer (PMMA) is suitable as substrate.

In the invention, the repetition unit of the pattern comprises at least two pixels. A pixel is actually a sub unit of the repetition unit. Semiconductor nanoparticles are localized inside the area defined by a pixel. Alternatively, a pixel may define an area void of semiconductor nanoparticles. In the invention, at least on pixel of the periodic pattern is filled with semiconductor nanoparticles. Consequently, fluorescent film of the invention comprises deposits of semiconductor nanoparticles distributed on a periodic pattern.

In the invention, semiconductor nanoparticles have at least one of:
a longest dimension greater than 25 nm, preferably greater than 30 nm, more preferably greater than 40 nm; or
an aspect ratio greater than 1.5, preferably greater than 3.

Actually, a size larger than 25 nm along the longest dimension or an anisotropic shape is favorable for deposition of semiconductor nanoparticles on substrate, in particular under di-electrophoretic conditions, in which attraction forces are more efficient for large and/or anisotropic semiconductor nanoparticles. Furthermore, the conversion ratio of the fluorescent film depends upon the size of the semiconductor nanoparticles as it defines the thickness of the layer of nanoparticles deposited on the substrate.

In the invention, the fluorescent film is not necessarily fluorescent over the whole surface of the substrate. Fluorescence is an intrinsic property of semiconductor nanoparticles which are on the substrate. These particles may cover all the surface of the substrate or may cover a part of the surface of the substrate, depending on the pattern selected.

According to an embodiment, the pattern is periodic in two dimensions, preferably the periodic pattern is a rectangular lattice or a square lattice. Such periodic patterns allow for easy localization of each elementary unit on the fluorescent film, which is desirable to address illumination of each elementary unit with a primary light source.

According to an embodiment, semiconductor nanoparticles are inorganic, in particular, semiconductor nanoparticles may be semiconductor nanocrystals comprising a material of formula

MₓQ_{y}E_{z}A_{w} (I)

wherein:
M is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs or a mixture thereof;
Q is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs or a mixture thereof;
E is selected from the group consisting of O, S, Se, Te, C, N, P, As, Sb, F, Cl, Br, I, or a mixture thereof;
A is selected from the group consisting of O, S, Se, Te, C, N, P, As, Sb, F, Cl, Br, I, or a mixture thereof; and
x, y, z and w are independently a rational number from 0 to 5; x, y, z and w are not simultaneously equal to 0; x and y are not simultaneously equal to 0; z and w are not simultaneously equal to 0.

Preferably, semiconductor nanoparticles are so-called quantum dots, i.e. semiconductor nanoparticles having one of their dimensions lower than the Bohr radius of electron-hole pair in the material.

Herein, the formulas MₓQ_{y}E_{z}A_{w} (I) and MₓN_{y}E_{z}A_{w} can be used interchangeably (wherein Q or N is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs).

In one embodiment, semiconductor nanoparticles comprise a semiconductor material selected from the group consisting of group IV, group IIIA-VA, group IIA-VIA, group IIIA-VIA, group IA-IIIA-VIA, group IIA-VA, group IVA-VIA, group VIB-VIA, group VB-VIA, group IVB-VIA or mixture thereof.

In a specific configuration of this embodiment, semiconductor nanocrystals have a homostructure. By homostructure, it is meant that each particle is homogenous and has the same local composition in all its volume. In other words, each particle is a core particle without a shell.

In a specific configuration of this embodiment, semiconductor nanocrystals have a core/shell structure. The core comprises a material of formula MₓQ_{y}E_{z}A_{w} as defined above. The shell comprises a material different from core of formula MₓQ_{y}E_{z}A_{w} as defined above, such as a material of formula

M′_{x′}Q′_{y′}E′_{z′}A′_{w′} (II)

wherein:
M′ is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs;
Q′ is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs;
E′ is selected from the group consisting of O, S, Se, Te, C, N, P, As, Sb, F, Cl, Br, I;
A′ is selected from the group consisting of O, S, Se, Te, C, N, P, As, Sb, F, Cl, Br, I; and
x′, y′, z′ and w are independently a decimal number from 0 to 5; x′, y′, z′ and w′ are not simultaneously equal to 0; x′ and y′ are not simultaneously equal to 0; z′ and w′ may not be simultaneously equal to 0.

In a more specific configuration of this embodiment, semiconductor nanocrystals have a core/first-shell/second-shell structure (i.e. core/shell/shell structure). The core comprises a material of formula MₓQ_{y}E_{z}A_{w} as defined above. The first-shell comprises a material different from core of formula MₓQ_{y}E_{z}A_{w} as defined above. The second-shell is deposited partially or totally on the first-shell with the same features or different features than the first-shell, such as for example same or different thickness. The material of second-shell is different from the material of the first shell and/or of the material of the core. By analogy, structures with three or four shells may be prepared.

In a specific configuration of this embodiment, semiconductor nanocrystals have a core/crown structure. The embodiments concerning shells apply mutatis mutandis to crowns in terms of composition, thickness, properties, number of layers of material.

In a configuration of this embodiment, semiconductor nanoparticles are colloidal nanoparticles.

In a configuration of this embodiment, semiconductor nanoparticles are electrically neutral. With electrically neutral semiconductor nanoparticles, it is easier to manage deposition on substrate, especially when deposition is driven by electrical polarization.

In a specific configuration of this embodiment, semiconductor nanoparticles emit red light by fluorescence. Emitted red light is typically a band centered on a wavelength shorter than 720 nm and longer than 600 nm, preferably shorter than 670 nm and longer than 620 nm, more preferably shorter than 635 nm and longer than 625 nm. Emitted red light is typically a band having a FWHM less than 50 nm, preferably less than 30 nm, more preferably less than 20 nm, i.e. a FWHM less than 0.16 eV, preferably less than 0.096 eV, more preferably less than 0.064 eV.

In a specific configuration of this embodiment, semiconductor nanoparticles emit green light by fluorescence. Emitted green light is typically a band centered on a wavelength shorter than 600 nm and longer than 500 nm, preferably shorter than 550 nm and longer than 520 nm, more preferably shorter than 535 nm and longer than 525 nm. Emitted green light is typically a band having a FWHM less than 50 nm, preferably less than 30 nm, more preferably less than 20 nm, i.e. FWHM less than 0.22 eV, preferably less than 0.13 eV, more preferably less than 0.08 eV.

In a specific configuration of this embodiment, semiconductor nanoparticles emit blue light by fluorescence. Emitted blue light is typically a band centered on a wavelength shorter than 500 nm and longer than 400 nm, preferably shorter than 480 nm and longer than 420 nm, more preferably shorter than 455 nm and longer than 435 nm. Emitted blue light is typically a band having a FWHM less than 50 nm, preferably less than 30 nm, more preferably less than 20 nm, i.e. a FWHM less than 0.306 eV, preferably less than 0.184 eV, more preferably less than 0.122 eV.

In a configuration of this embodiment, semiconductor nanoparticles are selected from CdSeₓS₍₁₋ₓ₎/CdS/ZnS, CdSeₓS₍₁₋ₓ₎/Cd_{y}Zn_{(1-y)}S, CdSeₓS₍₁₋ₓ₎/ZnS, CdSeₓS₍₁₋ₓ₎/Cd_{y}Zn_{(1-y)}S/ZnS, CdSeₓS₍₁₋ₓ₎/CdS, CdSe/CdS/ZnS, CdSe/CdS, CdSe/Cd_{y}Zn_{(1-y)}S, CdSe/Cd_{y}Zn_{(1-y)}S/ZnS, CdSeₓS₍₁₋ₓ₎/CdS/ZnSe, CdSeₓS₍₁₋ₓ₎/Cd_{y}Zn_{(1-y)}Se, CdSeₓS₍₁₋ₓ₎/ZnSe, CdSeₓS₍₁₋ₓ₎/Cd_{y}Zn_{(1-y)}Se/ZnSe, CdSeₓS₍₁₋ₓ₎/Cd_{y}Zn_{(1-y)}Se/ZnS, CdSe/CdS/ZnSe, CdSe/Cd_{y}Zn_{(1-y)}Se, CdSe/Cd_{y}Zn_{(1-y)}Se/ZnSe CdSe/Cd_{y}Zn_{(1-y)}Se/ZnS, CdSeₓS₍₁₋ₓ₎/CdS/ZnSe_{y}S_{(1-y)}, CdSeₓS₍₁₋ₓ₎/Cd_{y}Zn_{(1-y)}S, CdSeₓS₍₁₋ₓ₎/ZnSe_{y}S_{(1-y)}, CdSeₓS₍₁₋ₓ₎/Cd_{y}Zn_{(1-y)}S/ZnSe_{z}S_{(1-z)}, CdSeₓS₍₁₋ₓ₎/CdS, CdSe/CdS/ZnSe_{y}S_{(1-y)}, CdSe/CdS, CdSe/Cd_{y}Zn_{(1-y)}S, CdSe/Cd_{y}Zn_{(1-y)}S/ZnSe_{z}S_{(1-z)}, CdSeₓS₍₁₋ₓ₎/CdS/ZnSe_{y}S_{(1-y)}, CdSeₓS₍₁₋ₓ₎/Cd_{y}Zn_{(1-y)}Se, CdSeₓS₍₁₋ₓ₎/ZnSe_{y}S_{(1-y)}, CdSeₓS₍₁₋ₓ₎/Cd_{y}Zn_{(1-y)}Se/ZnSe_{z}S_{(1-z)}, CdSeₓS₍₁₋ₓ₎/Cd_{y}Zn_{(1-y)}Se/ZnSe_{z}S_{(1-z)}, CdSe/Cd_{y}Zn_{(1-y)}Se, CdSe/Cd_{y}Zn_{(1-y)}Se/ZnSe_{z}S_{(1-z)}, CdSe/Cd_{y}Zn_{(1-y)}Se/ZnSe_{z}S_{(1-z)} where x, y and z are rational numbers between 0 (excluded) and 1 (excluded), and emit red light by fluorescence. Emitted red light is typically a band centered on a wavelength shorter than 720 nm and longer than 600 nm, preferably shorter than 670 nm and longer than 620 nm, more preferably shorter than 635 nm and longer than 625 nm. Emitted red light is typically a band having a FWHM less than 50 nm, preferably less than 30 nm, more preferably less than 20 nm. Suitable semiconductor nanoparticles emitting red light at 630 nm are core/shell/shell nanoplatelets of CdSe_{0.45}S_{0.55}/Cd_{0.30}Zn_{0.70}S/ZnS, with a core of thickness 1.2 nm and a lateral dimension, i.e. length or width, greater than 8 nm and shells of thicknesses 2.5 nm and 2 nm. Other suitable semiconductor nanoparticles emitting red light at 630 nm are core/shell/shell nanoplatelets of CdSe_{0.65}S_{0.35}/CdS/ZnS, with a core of thickness 1.2 nm and a lateral dimension, i.e. length or width, greater than 8 nm and shells of thicknesses 2.5 nm and 2 nm.

In a configuration of this embodiment, semiconductor nanoparticles are selected from CdSeₓS₍₁₋ₓ₎/CdS/ZnS, CdSeₓS₍₁₋ₓ₎/Cd_{y}Zn_{(1-y)}S, CdSeₓS₍₁₋ₓ₎/ZnS, CdSeₓS₍₁₋ₓ₎/Cd_{y}Zn_{(1-y)}S/ZnS, CdSeₓS₍₁₋ₓ₎/CdS, CdSe/CdS/ZnS, CdSe/CdS, CdSe/Cd_{y}Zn_{(1-y)}S, CdSe/Cd_{y}Zn_{(1-y)}S/ZnS, CdSeₓS₍₁₋ₓ₎/CdS/ZnSe, CdSeₓS₍₁₋ₓ₎/Cd_{y}Zn_{(1-y)}Se, CdSeₓS₍₁₋ₓ₎/ZnSe, CdSeₓS₍₁₋ₓ₎/Cd_{y}Zn_{(1-y)}Se/ZnSe, CdSeₓS₍₁₋ₓ₎/Cd_{y}Zn_{(1-y)}Se/ZnS, CdSe/CdS/ZnSe, CdSe/Cd_{y}Zn_{(1-y)}Se, CdSe/Cd_{y}Zn_{(1-y)}Se/ZnSe CdSe/Cd_{y}Zn_{(1-y)}Se/ZnS, CdS/ZnSe, CdSeₓS₍₁₋ₓ₎/ZnS/Cd_{y}Zn_{(1-y)}S/ZnS, CdS/ZnS, CdS/Cd_{y}Zn_{(1-y)}S, CdS/Cd_{y}Zn_{(1-y)}S/ZnS, CdS/ZnSe, CdS/Cd_{y}Zn_{(1-y)}Se, CdS/ZnSe, CdS/Cd_{y}Zn_{(1-y)}Se/ZnSe, CdS/Cd_{y}Zn_{(1-y)}Se/ZnS, CdS/ZnSe, CdS/ZnS/Cd_{y}Zn_{(1-y)}S/ZnS, CdSeₓS₍₁₋ₓ₎/CdS/ZnSe_{z}S_{(1-z)}, CdSeₓS₍₁₋ₓ₎/Cd_{y}Zn_{(1-y)}S, CdSeₓS₍₁₋ₓ₎/ZnSe_{z}S_{(1-z)}, CdSeₓS₍₁₋ₓ₎/Cd_{y}Zn_{(1-y)}S/ZnSe_{z}S_{(1-z)}, CdSeₓS₍₁₋ₓ₎/CdS, CdSeₓS₍₁₋ₓ₎/Cd_{y}Zn_{(1-y)}Se, CdSeₓS₍₁₋ₓ₎/ZnSe_{z}S_{(1-z)}, CdSeₓS₍₁₋ₓ₎/Cd_{y}Zn_{(1-y)}Se/ZnSe_{z}S_{(1-z)}, CdS/ZnSe_{z}S_{(1-z)}, CdSeₓS₍₁₋ₓ₎/ZnSe_{z}S_{(1-z)}/Cd_{y}Zn_{(1-y)}S/ZnS, CdSeₓS₍₁₋ₓ₎/ZnSe_{z}S_{(1-z)}/Cd_{y}Zn_{(1-y)}S/ZnSe_{z}S_{(1-z)}, CdS/Cd_{y}Zn_{(1-y)}S, CdS/Cd_{y}Zn_{(1-y)}S/ZnSe_{z}S_{(1-z)}, CdS/Cd_{y}Zn_{(1-y)}Se, CdS/ZnSe_{z}S_{(1-z)}, CdS/ZnSe_{z}S_{(1-z)}/Cd_{y}Zn_{(1-y)}S/ZnS, CdS/ZnSe_{z}S_{(1-z)}/Cd_{y}Zn_{(1-y)}S/ZnSe_{z}S_{(1-z)}, CdS/ZnS/Cd_{y}Zn_{(1-y)}S/ZnSe_{z}S_{(1-z)}, Cd_{y}Zn_{(1-y)}Se/ZnSe/ZnSe_{z}S_{(1-z)}/ZnS where x, y and z are rational numbers between 0 (excluded) and 1 (excluded), and emit green light by fluorescence. Emitted green light is typically a band centered on a wavelength shorter than 600 nm and longer than 500 nm, preferably shorter than 550 nm and longer than 520 nm, more preferably shorter than 535 nm and longer than 525 nm. Emitted green light is typically a band having a FWHM less than 50 nm, preferably less than 30 nm, more preferably less than 20 nm. Suitable semiconductor nanoparticles emitting green light at 530 nm are core/shell/shell nanoplatelets of CdSe_{0.10}S_{0.90}/ZnS/Cd_{0.20}Zn_{0.80}S, with a core of thickness 1.5 nm and a lateral dimension, i.e. length or width, greater than 10 nm and shells of thicknesses 1 nm and 2.5 nm. Other suitable semiconductor nanoparticles emitting green light at 530 nm are core/shell/shell nanoplatelets of CdSe_{0.20}S_{0.80}/ZnS/Cd_{0.15}Zn_{0.85}S, with a core of thickness 1.2 nm and a lateral dimension, i.e. length or width, greater than 10 nm and shells of thicknesses 1 nm and 2.5 nm.

In a configuration of this embodiment, semiconductor nanoparticles are selected from CdS/ZnSe, CdS/ZnS, CdS/Cd_{y}Zn_{(1-y)}S, CdS/Cd_{y}Zn_{(1-y)}S/ZnS, CdS/Cd_{y}Zn_{(1-y)}Se, CdS/Cd_{y}Zn_{(1-y)}Se/ZnSe, CdS/Cd_{y}Zn_{(1-y)}Se/ZnS, CdS/ZnS/Cd_{y}Zn_{(1-y)}S/ZnS, CdS/ZnSe_{z}S_{(1-z)}, CdS/Cd_{y}Zn_{(1-y)}S, CdS/Cd_{y}Zn_{(1-y)}S/ZnSe_{z}S_{(1-z)}, CdS/Cd_{y}Zn_{(1-y)}Se, CdS/ZnSe_{z}S_{(1-z)}, CdS/ZnSe_{z}S_{(1-z)}/Cd_{y}Zn_{(1-y)}S/ZnS, CdS/ZnSe_{z}S_{(1-z)}/Cd_{y}Zn_{(1-y)}S/ZnSe_{z}S_{(1-z)}, CdS/ZnS/Cd_{y}Zn_{(1-y)}S/ZnSe_{z}S_{(1-z)}, where x, y and z are rational numbers between 0 (excluded) and 1 (excluded), and emit blue light by fluorescence (when stimulated by Ultra-violet light). Emitted blue light is typically a band centered on a wavelength shorter than 500 nm and longer than 400 nm, preferably shorter than 480 nm and longer than 420 nm, more preferably shorter than 455 nm and longer than 435 nm. Emitted blue light is typically a band having a FWHM less than 50 nm, preferably less than 30 nm, more preferably less than 20 nm. Suitable semiconductor nanoparticles emitting blue light at 450 nm are core/shell nanoplatelets of CdS/ZnS, with a core of thickness 0.9 nm and a lateral dimension, i.e. length or width, greater than 15 nm and a shell of thickness 1 nm.

According to an embodiment, semiconductor nanoparticles are anisotropic and have an aspect ratio greater than 1.5. In some embodiments, semiconductor nanoparticles have an aspect ratio greater than 1.5, 2, 2.5, 3, 3.5, 4, 4.5, 5, 6, 7, 8, 9, 10, 15, 20. Semiconductor nanoparticles may have an ovoid shape, a discoidal shape, a cylindrical shape, a faceted shape, a hexagonal shape, a triangular shape, or a platelet shape. In a specific aspect of this embodiment, semiconductor nanoparticles are on the substrate with their longest dimension substantially aligned in a predetermined direction. Such orientation of semiconductor nanoparticles allows for compact deposition, which has three advantages.

First, thickness of deposit is reduced for a same quantity of semiconductor nanoparticles deposited and a thin fluorescent film is desirable for manufacturing reasons. Second, compact deposit avoids that light emitted by primary light source can go through semiconductor nanoparticles without being absorbed. Indeed, with a compact deposit, one can expect an improved yield of light emission for a same amount of primary light arriving on semiconductor nanoparticles. Last, a good vertical stacking and assembly of semiconductor nanoparticles permit a better control of the thickness of the fluorescent film. In this embodiment, “substantially aligned in a predetermined direction” means that at least 50% of the nanoparticles are aligned in a predetermined direction, preferably at least 60% of the nanoparticles are aligned in a predetermined direction, more preferably at least 70% of the nanoparticles are aligned in a predetermined direction, most preferably at least 90% of the nanoparticles are aligned in a predetermined direction.

According to an embodiment, semiconductor nanoparticles have a longest dimension greater than 25 nanometers and an aspect ratio greater than 1.5 Actually, the association of anisotropy and a size larger than 25 nm along the longest dimension is favorable for deposition of semiconductor nanoparticles on substrate, in particular under di-electrophoretic conditions, in which electro-rotation phenomenon takes place, and more particularly for deposition in an oriented manner.

FWHM of emission spectra of semiconductor nanoplatelets is lower than for quantum dots: emission bands are narrower, and the typical photoluminescence decay time of semiconductor nanoplatelets is 1 order of magnitude faster than for spherical quantum dots.

Preferably, the semiconductor nanoparticles have a 1D shape (cylindrical shape) or a 2D shape (platelet shape). Advantageously, a 1D shape allows confinement of excitons in two dimensions and allows free propagation in the other dimension, a 2D shape allows confinement of excitons in one dimension and allows free propagation in the other two dimensions, whereas a quantum dot (or spherical nanocrystal) has a 3D shape and allow confinement of excitons in all three spatial dimensions. These particular 2D and 1D confinements result in distinct electronic and optical properties, for example a faster photoluminescence decay time and a narrower optical feature with full width at half maximum (FWHM) much lower than for spherical quantum dots.

It is worth noting that quantum dots and semiconductor nanoplatelets are quite different regarding their optical properties, but also regarding their morphology and their surface chemistry:
the organization of M and E atoms (for a formula MₓE_{z}) at the surface of a nanoplatelet and at the surface of a quantum dot are different;
nanoplatelets have specific exposed crystalline facets different from quantum dots; and
nanoplatelets have a higher specific surface than quantum dots (this is valid for a nanoplatelet having a thickness R and a quantum dot having the same diameter R, wherein lateral dimensions of the nanoplatelet being superior to 5/3R).

According to an embodiment, semiconductor nanoparticles are on two of the at least two pixels and semiconductor nanoparticles on the first pixel of the at least two pixels are different from semiconductor nanoparticles on the second pixel of the at least two pixels. With such a configuration, the fluorescent film emits two different lights allowing for dichromatic device. In a preferred embodiment, the periodic pattern comprises three pixels, one pixel being void of semiconductor nanoparticles and two pixels comprising each one type of semiconductor nanoparticles. In particular, a first pixel void of semiconductor nanoparticles, a second pixel comprising semiconductor nanoparticles absorbing blue light and with light emission in green range and a third pixel comprising semiconductor nanoparticles absorbing blue light and with light emission in red range is preferred. Green and red ranges are defined as above.

According to an embodiment, substrate comprises a primary light source, preferably a LED, more preferably a blue LED with emission spectrum in a range from 370 nm to 480 nm. In an advantageous embodiment, primary light source is covered with a layer of electret material, so that substrate surface is electret. Primary light sources may be distributed according to the same periodic pattern on which semiconductor nanoparticles are distributed, preferably so that each primary light source corresponds to a pixel of the periodic pattern.

In this embodiment, a preferred substrate is an array of blue LEDs under a glass substrate coated with a layer of Indium Tin Oxide (ITO) and a layer of PMMA.

In another embodiment, substrate is a soft material, for instance a polymeric material, preferably an electret material, configured to be transferred on a support comprising primary light source. By transferred, it is meant any method yielding a structure comprising said soft material on the support comprising primary light source. Transfer may be direct, without any material between substrate and support: this is direct contact between substrate and support. Transfer may use an adhesive between substrate and support. Transfer may use an intermediate carrier. This embodiment enables production of large pieces of substrate which may be stored for some time before being cut on demand and reported on support comprising primary light source.

According to an embodiment, semiconductor nanoparticles are deposited with a thickness of less than 10000 nm and more than 100 nm, preferably less than 3000 nm and more than 200 nm. Indeed, to avoid that light emitted by primary light source can go through semiconductor nanoparticles without being absorbed, inventors identified that a thickness of more than 100 nm is preferred.

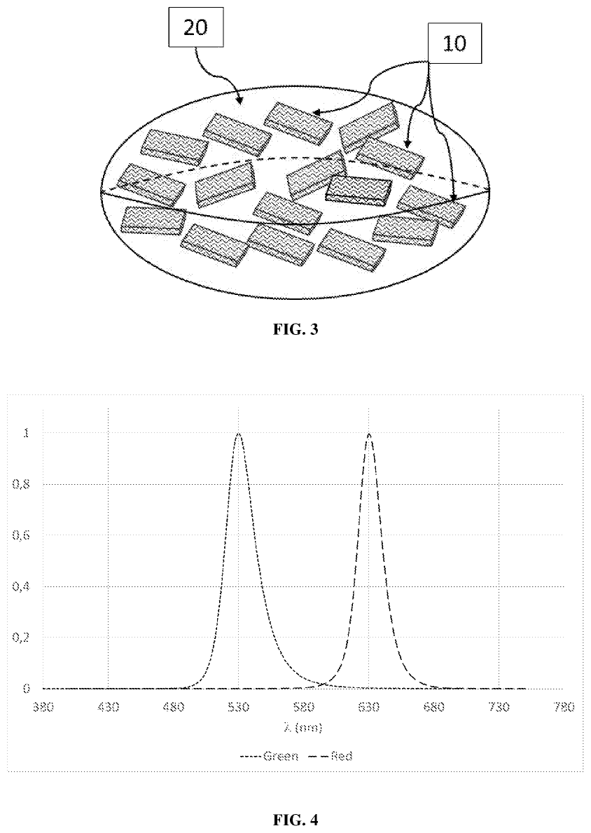

According to an embodiment, semiconductor nanoparticles are composite nanoparticles comprising fluorescent semiconductor nanoparticles (10) encapsulated in a matrix (20) as shown on FIG. 3. Composite particles may be anisotropic or isotropic. Composite nanoparticles have two advantages. As their size is larger than single fluorescent semiconductor nanoparticles, di-electrophoretic forces are more efficient and deposition is quicker than for single fluorescent semiconductor nanoparticles. In addition, composite nanoparticles allow for deposition of thicker layers, up to micrometer scale. Last, matrix may be selected to be metastable. By metastable, it is meant that composite is stable for some time, typically during deposition of nanoparticles on the substrate. But, in a later stage, specific external conditions such as heat, irradiation, ultrasound, pH change or solvent change may be imposed to composite nanoparticles and lead to a degradation of matrix and release of fluorescent semiconductor nanoparticles. Metastable composite nanoparticles yield an improved deposition due to size of composite but without diluting fluorescent semiconductor nanoparticles in an inert matrix.

In this embodiment, composite nanoparticles may be spherical or anisotropic.

In a specific embodiment, fluorescent semiconductor nanoparticles (10) are nanoparticles having a longest dimension greater than 25 nanometers, such as nanoplatelets described above.

In another specific embodiment, fluorescent semiconductor nanoparticles (10) are nanoparticles whose longest dimension is less than 25 nanometers. By encapsulation in a matrix (20), said fluorescent semiconductor nanoparticles may be manipulated as nanoparticles having a longest dimension greater than 25 nanometers with advantages of the invention already described.

In a specific embodiment, fluorescent semiconductor nanoparticles (10) are nanoparticles having an aspect ratio greater than 1.5, such as nanoplatelets described above, or nanoparticles having an aspect ratio of 1 such as quantum dots as described above.

In a configuration of this embodiment, fluorescent semiconductor nanoparticles are semiconductor nanoparticles as described above.

In a configuration of this embodiment, fluorescent semiconductor nanoparticles are selected from InP/ZnS, InP/CdₓZn₍₁₋ₓ₎S, InP/ZnSe/ZnS, InP/CdₓZn₍₁₋ₓ₎S/ZnS, InP/ZnSe/ZnS, InP/ZnSeₓS₍₁₋ₓ₎/ZnS, InP/CdₓZn₍₁₋ₓ₎S/ZnSe, InP/ZnSe, InP/CdₓZn₍₁₋ₓ₎Se, InP/CdₓZn₍₁₋ₓ₎Se/ZnS, InP/ZnSeₓS₍₁₋ₓ₎, CdSeₓS₍₁₋ₓ₎/CdS/ZnS, CdSeₓS₍₁₋ₓ₎/Cd_{y}Zn_{(1-y)}S, CdSeₓS₍₁₋ₓ₎/ZnS, CdSeₓS₍₁₋ₓ₎/Cd_{y}Zn_{(1-y)}S/ZnS, CdSeₓS₍₁₋ₓ₎/CdS, CdSe/CdS/ZnS, CdSe/CdS, CdSe/Cd_{y}Zn_{(1-y)}S, CdSe/Cd_{y}Zn_{(1-y)}S/ZnS, CdSeₓS₍₁₋ₓ₎/CdS/ZnSe, CdSeₓS₍₁₋ₓ₎/Cd_{y}Zn_{(1-y)}Se, CdSeₓS₍₁₋ₓ₎/ZnSe, CdSeₓS₍₁₋ₓ₎/Cd_{y}Zn_{(1-y)}Se/ZnSe, CdSeₓS₍₁₋ₓ₎/Cd_{y}Zn_{(1-y)}Se/ZnS, CdSe/CdS/ZnSe, CdSe/Cd_{y}Zn_{(1-y)}Se, CdSe/Cd_{y}Zn_{(1-y)}Se/ZnSe CdSe/Cd_{y}Zn_{(1-y)}Se/ZnS, CdSeₓS₍₁₋ₓ₎/CdS/ZnSe_{y}S_{(1-y)}, CdSeₓS₍₁₋ₓ₎/Cd_{y}Zn_{(1-y)}S, CdSeₓS₍₁₋ₓ₎/ZnSe_{y}S_{(1-y)}, CdSeₓS₍₁₋ₓ₎/Cd_{y}Zn_{(1-y)}S/ZnSe_{z}S_{(1-z)}, CdSeₓS₍₁₋ₓ₎/CdS, CdSe/CdS/ZnSe_{y}S_{(1-y)}, CdSe/CdS, CdSe/Cd_{y}Zn_{(1-y)}S, CdSe/Cd_{y}Zn_{(1-y)}S/ZnSe_{z}S_{(1-z)}, CdSeₓS₍₁₋ₓ₎/CdS/ZnSe_{y}S_{(1-y)}, CdSeₓS₍₁₋ₓ₎/Cd_{y}Zn_{(1-y)}Se, CdSeₓS₍₁₋ₓ₎/ZnSe_{y}S_{(1-y)}, CdSeₓS₍₁₋ₓ₎/Cd_{y}Zn_{(1-y)}Se/ZnSe_{y}S_{(1-z)}, CdSeₓS₍₁₋ₓ₎/Cd_{y}Zn_{(1-y)}Se/ZnSe_{z}S_{(1-z)}, CdSe/Cd_{y}Zn_{(1-y)}Se, CdSe/Cd_{y}Zn_{(1-y)}Se/ZnSe_{z}S_{(1-z)}, CdSe/Cd_{y}Zn_{(1-y)}Se/ZnSe_{z}S_{(1-z)} where x, y and z are rational numbers between 0 (excluded) and 1 (excluded) and emit red light by fluorescence. Emitted red light is typically a band centered on a wavelength shorter than 720 nm and longer than 600 nm, preferably shorter than 670 nm and longer than 620 nm, more preferably shorter than 635 nm and longer than 625 nm. Emitted red light is typically a band having a FWHM less than 50 nm, preferably less than 30 nm, more preferably less than 20 nm. Suitable fluorescent semiconductor nanoparticles emitting red light at 630 nm with FWHM of 45 nm are core/shell/shell spherical nanoparticles of InP/ZnSe_{0.50}S_{0.50}/ZnS, with a core of diameter 3.5 nm, a first shell thickness of 2 nm and a second shell thickness of 1 nm for a nanoparticle diameter of 9.5 nm. Suitable fluorescent semiconductor nanoparticles emitting red light at 630 nm are core/shell/shell nanoplatelets of CdSe_{0.45}S_{0.55}/Cd_{0.30}Zn_{0.70}S/ZnS, with a core of thickness 1.2 nm and a lateral dimension, i.e. length or width, greater than 8 nm and shells of thicknesses 2.5 nm and 2 nm. Other fluorescent suitable semiconductor nanoparticles emitting red light at 630 nm are core/shell/shell nanoplatelets of CdSe_{0.65}S_{0.35}/CdS/ZnS, with a core of thickness 1.2 nm and a lateral dimension, i.e. length or width, greater than 8 nm and shells of thicknesses 2.5 nm and 2 nm.

In another configuration of this embodiment, fluorescent semiconductor nanoparticles are selected from InP/ZnS, InP/CdₓZn₍₁₋ₓ₎S, InP/ZnSe/ZnS, InP/CdₓZn₍₁₋ₓ₎S/ZnS, InP/ZnSe/ZnS, InP/ZnSeₓS₍₁₋ₓ₎/ZnS, InP/CdₓZn₍₁₋ₓ₎S/ZnSe, InP/ZnSe, InP/CdₓZn₍₁₋ₓ₎Se, InP/CdₓZn₍₁₋ₓ₎Se/ZnS, InP/ZnSeₓS₍₁₋ₓ₎, CdSeₓS₍₁₋ₓ₎/CdS/ZnS, CdSeₓS₍₁₋ₓ₎/Cd_{y}Zn_{(1-y)}S, CdSeₓS₍₁₋ₓ₎/ZnS, CdSeₓS₍₁₋ₓ₎/Cd_{y}Zn_{(1-y)}S/ZnS, CdSeₓS₍₁₋ₓ₎/CdS, CdSe/CdS/ZnS, CdSe/CdS, CdSe/Cd_{y}Zn_{(1-y)}S, CdSe/Cd_{y}Zn_{(1-y)}S/ZnS, CdSeₓS₍₁₋ₓ₎/CdS/ZnSe, CdSeₓS₍₁₋ₓ₎/Cd_{y}Zn_{(1-y)}Se, CdSeₓS₍₁₋ₓ₎/ZnSe, CdSeₓS₍₁₋ₓ₎/Cd_{y}Zn_{(1-y)}Se/ZnSe, CdSeₓS₍₁₋ₓ₎/Cd_{y}Zn_{(1-y)}Se/ZnS, CdSe/CdS/ZnSe, CdSe/Cd_{y}Zn_{(1-y)}Se, CdSe/Cd_{y}Zn_{(1-y)}Se/ZnSe CdSe/Cd_{y}Zn_{(1-y)}Se/ZnS, CdS/ZnSe, CdSeₓS₍₁₋ₓ₎/ZnS/Cd_{y}Zn_{(1-y)}S/ZnS, CdS/ZnS, CdS/Cd_{y}Zn_{(1-y)}S, CdS/Cd_{y}Zn_{(1-y)}S/ZnS, CdS/ZnSe, CdS/Cd_{y}Zn_{(1-y)}Se, CdS/ZnSe, CdS/Cd_{y}Zn_{(1-y)}Se/ZnSe, CdS/Cd_{y}Zn_{(1-y)}Se/ZnS, CdS/ZnSe, CdS/ZnS/Cd_{y}Zn_{(1-y)}S/ZnS, CdSeₓS₍₁₋ₓ₎/CdS/ZnSe_{z}S_{(1-z)}, CdSeₓS₍₁₋ₓ₎/Cd_{y}Zn_{(1-y)}S, CdSeₓS₍₁₋ₓ₎/ZnSe_{z}S_{(1-z)}, CdSeₓS₍₁₋ₓ₎/Cd_{y}Zn_{(1-y)}S/ZnSe_{z}S_{(1-z)}, CdSeₓS₍₁₋ₓ₎/CdS, CdSeₓS₍₁₋ₓ₎/Cd_{y}Zn_{(1-y)}Se, CdSeₓS₍₁₋ₓ₎/ZnSe_{z}S_{(1-z)}, CdSeₓS₍₁₋ₓ₎/Cd_{y}Zn_{(1-y)}Se/ZnSe_{z}S_{(1-z)}, CdS/ZnSe_{z}S_{(1-z)}, CdSeₓS₍₁₋ₓ₎/ZnSe_{z}S_{(1-z)}/Cd_{y}Zn_{(1-y)}S/ZnS, CdSeₓS₍₁₋ₓ₎/ZnSe_{z}S_{(1-z)}/Cd_{y}Zn_{(1-y)}S/ZnSe_{z}S_{(1-z)}, CdS/Cd_{y}Zn_{(1-y)}S, CdS/Cd_{y}Zn_{(1-y)}S/ZnSe_{z}S_{(1-z)}, CdS/Cd_{y}Zn_{(1-y)}Se, CdS/ZnSe_{z}S_{(1-z)}, CdS/ZnSe_{z}S_{(1-z)}/Cd_{y}Zn_{(1-y)}S/ZnS, CdS/ZnSe_{z}S_{(1-z)}/Cd_{y}Zn_{(1-y)}S/ZnSe_{z}S_{(1-z)}, CdS/ZnS/Cd_{y}Zn_{(1-y)}S/ZnSe_{z}S_{(1-z)}, where x, y and z are rational numbers between 0 (excluded) and 1 (excluded) and emit green light by fluorescence. Emitted green light is typically a band centered on a wavelength shorter than 600 nm and longer than 500 nm, preferably shorter than 550 nm and longer than 520 nm, more preferably shorter than 535 nm and longer than 525 nm. Emitted green light is typically a band having a FWHM less than 50 nm, preferably less than 30 nm, more preferably less than 20 nm. Suitable fluorescent semiconductor nanoparticles emitting green light at 530 nm with FWHM of 40 nm are core/shell spherical nanoparticles of InP/ZnSe_{0.50}S_{0.50}, with a core of diameter 2.5 nm and a shell thickness of 2.5 nm for a nanoparticle diameter of 7.5 nm. Suitable fluorescent semiconductor nanoparticles emitting green light at 530 nm are core/shell/shell nanoplatelets of CdSe_{0.10}S_{0.90}/ZnS/Cd_{0.20}Zn_{0.80}S, with a core of thickness 1.5 nm and a lateral dimension, i.e. length or width, greater than 10 nm and shells of thicknesses 1 nm and 2.5 nm. Other suitable fluorescent semiconductor nanoparticles emitting green light at 530 nm are core/shell/shell nanoplatelets of CdSe_{0.20}S_{0.80}/ZnS/Cd_{0.15}Zn_{0.85}S, with a core of thickness 1.2 nm and a lateral dimension, i.e. length or width, greater than 10 nm and shells of thicknesses 1 nm and 2.5 nm.

In a configuration of this embodiment, fluorescent semiconductor nanoparticles are selected from CdS/ZnSe, CdS/ZnS, CdS/Cd_{y}Zn_{(1-y)}S, CdS/Cd_{y}Zn_{(1-y)}S/ZnS, CdS/Cd_{y}Zn_{(1-y)}Se, CdS/Cd_{y}Zn_{(1-y)}Se/ZnSe, CdS/Cd_{y}Zn_{(1-y)}Se/ZnS, CdS/ZnS/Cd_{y}Zn_{(1-y)}S/ZnS, CdS/ZnSe_{z}S_{(1-z)}, CdS/Cd_{y}Zn_{(1-y)}S, CdS/Cd_{y}Zn_{(1-y)}S/ZnSe_{z}S_{(1-z)}, CdS/Cd_{y}Zn_{(1-y)}Se, CdS/ZnSe_{z}S_{(1-z)}, CdS/ZnSe_{z}S_{(1-z)}/Cd_{y}Zn_{(1-y)}S/ZnS, CdS/ZnSe_{z}S_{(1-z)}/Cd_{y}Zn_{(1-y)}S/ZnSe_{z}S_{(1-z)}, CdS/ZnS/Cd_{y}Zn_{(1-y)}S/ZnSe_{z}S_{(1-z)}, where x, y and z are rational numbers between 0 (excluded) and 1 (excluded), and emit blue light by fluorescence (when stimulated by Ultra-violet light). Emitted blue light is typically a band centered on a wavelength shorter than 500 nm and longer than 400 nm, preferably shorter than 480 nm and longer than 420 nm, more preferably shorter than 455 nm and longer than 435 nm. Emitted blue light is typically a band having a FWHM less than 50 nm, preferably less than 30 nm, more preferably less than 20 nm. Suitable fluorescent semiconductor nanoparticles emitting blue light at 450 nm are core/shell nanoplatelets of CdS/ZnS, with a core of thickness 0.9 nm and a lateral dimension, i.e. length or width, greater than 15 nm and a shell of thickness 1 nm.

In a configuration of this embodiment, matrix (20) is optically transparent, i.e. matrix (20) is optically transparent in the blue range, in the green range and/or in the red range.

In a configuration of this embodiment, matrix (20) is selected from SiO₂, Al₂O₃, TiO₂, ZrO₂, ZnO, MgO, SnO₂, Nb₂O₅, CeO₂, BeO, IrO₂, CaO, Sc₂O₃, NiO, Na₂O, BaO, K₂O, PbO, Ag₂O, V₂O₅, TeO₂, MnO, B₂O₃, P₂O₅, P₂O₃, P₄O₇, P₄O₅, P₄O₉, P₂O₆, PO, GeO₂, As₂O₃, Fe₂O₃, Fe₃O₄, Ta₂O₅, Li₂O, SrO, Y₂O₃, HfO₂, WO₂, MoO₂, Cr₂O₃, Tc₂O₇, ReO₂, RuO₂, CoO₄, OsO, RhO₂, Rh₂O₃, PtO, PdO, CuO, Cu₂O, CdO, HgO, Tl₂O, Ga₂O₃, In₂O₃, Bi₂O₃, Sb₂O₃, PoO₂, SeO₂, Cs₂O, La₂O₃, Pr₆O₁₁, Nd₂O₃, La₂O₃, Sm₂O₃, Eu₂O₃, Tb₄O₇, Dy₂O₃, Ho₂O₃, Er₂O₃, Tm₂O₃, Yb₂O₃, Lu₂O₃, Gd₂O₃, or a mixture thereof.

In a configuration of this embodiment, matrix (20) comprises a polymerizable or polymerized monomer or oligomer selected from:
Allyl monomers or allyl oligomers (i.e. a compound comprising an allyl group) such as for example diethylene glycol bis(allyl carbonate), ethylene glycol bis(allyl carbonate), oligomers of diethylene glycol bis(allyl carbonate), oligomers of ethylene glycol bis(allyl carbonate), bisphenol A bis(allyl carbonate), diallylphthalates such as diallyl phthalate, diallyl isophthalate and diallyl terephthalate, and mixtures thereof;
(Meth)acrylic monomers or (meth)acrylic oligomers (i.e. a compound comprising having acrylic or methacrylic groups) such as for example monofunctional (meth)acrylates or multifunctional (meth)acrylates;
Compounds used to prepare polyurethane or polythiourethane materials;
Monomer or oligomer having at least two isocyanate functions selected from symmetric aromatic diisocyanate such as 2,2′ Methylene diphenyl diisocyanate (2,2′ MD I), 4,4′ dibenzyl diisocyanate (4,4′ DBDI), 2,6 toluene diisocyanate (2,6 TDI), xylylene diisocyanate (XDI), 4,4′ Methylene diphenyl diisocyanate (4,4′ MDI) or asymmetric aromatic diisocyanate such as 2,4′ Methylene diphenyl diisocyanate (2,4′ MDI), 2,4′ dibenzyl diisocyanate (2,4′ DBDI), 2,4 toluene diisocyanate (2,4 TDI) or alicyclic diisocyanates such as Isophorone diisocyanate (IPDI), 2, 5(or 2, 6)-bis(iso-cyanatomethyl)-Bicyclo[2.2.1]heptane (NDI) or 4,4′ Diisocyanato-methylenedicyclohexane (H12MD I) or aliphatic diisocyanates such as hexamethylene diisocyanate (HDI) or mixtures thereof;
Monomer or oligomer having thiol function selected from Pentaerythritol tetrakis mercaptopropionate, Pentaerythritol tetrakis mercaptoacetate, 4-Mercaptomethyl-3,6-dithia-1,8-octanedithiol, 4-mercaptomethyl-1,8-dimercapto-3,6-dithiaoctane, 2,5-dimercaptomethyl-1,4-dithiane, 2,5-bis[(2-mercaptoethyl)thiomethyl]-1,4-dithiane, 4,8-dimercaptomethyl-1,11-dimercapto-3,6,9-trithiaundecane, 4,7-dimercaptomethyl-1,11-dimercapto-3,6,9-trithiaundecane, 5,7-dimercaptomethyl-1,11-dimercapto-3,6,9-trithiaundecane and mixture thereof;
Monomer or oligomer having epithio function selected from bis(2,3-epithiopropyl)sulfide, bis(2,3-epithiopropyl)disulfide and bis[4-(beta epithiopropylthio)phenyl]sulfide, bis[4-(beta-epithiopropyloxy)cyclohexyl]sulfide.
Monomers or oligomers selected from alkoxysilanes, alkylalkoxysilanes, epoxysilanes, epoxyalkoxysilanes, and mixtures thereof.

Alkoxysilanes may be selected among compounds having the formula: RₚSi(Z)₄₋ₚ in which the R groups, identical or different, represent monovalent organic groups linked to the silicon atom through a carbon atom, the Z groups are identical or different and represent hydrolyzable groups or hydrogen atoms, p is an integer ranging from 0 to 2.

Suitable alkoxysilanes may be selected in the group consisting of tetraethoxysilane Si(OC₂H₅)₄ (TEOS), tetramethoxysilane Si(OCH₃)₄ (TMOS), tetra(n-propoxy)silane, tetra(i-propoxy)silane, tetra(n-butoxy)silane, tetra(sec-butoxy)silane or tetra(t-butoxy)silane.

Alkylalkoxysilanes may be selected among compounds having the formula: RₙYₘSi(Z₁)₄₋ₙ₋ₘ in which the R groups, identical or different, represent monovalent organic groups linked to the silicon atom through a carbon atom, the Y groups, identical or different, represent monovalent organic groups linked to the silicon atom through a carbon atom, the Z groups are identical or different and represent hydrolyzable groups or hydrogen atoms, m and n are integers such that m is equal to 1 or 2 and n+m=1 or 2.

Epoxyalkoxysilanes may be selected among compounds having the formula: RₙYₘSi(Z₁)₄₋ₙ₋ₘ in which the R groups, identical or different, represent monovalent organic groups linked to the silicon atom through a carbon atom, the Y groups, identical or different, represent monovalent organic groups linked to the silicon atom through a carbon atom and containing at least one epoxy function, the Z groups are identical or different and represent hydrolyzable groups or hydrogen atoms, m and n are integers such that m is equal to 1 or 2 and n+m=1 or 2.

Suitable epoxysilanes may be selected from the group consisting of glycidoxy methyl trimethoxysilane, glycidoxy methyl triethoxysilane, glycidoxy methyl tripropoxysilane, α-glycidoxy ethyl trimethoxysilane, α-glycidoxy ethyl triethoxysilane, β-glycidoxy ethyl trimethoxysilane, β-glycidoxy ethyl triethoxysilane, β-glycidoxy ethyl tripropoxysilane, α-glycidoxy propyl trimethoxysilane, α-glycidoxy propyl triethoxysilane, α-glycidoxy propyl tripropoxysilane, β-glycidoxy propyl trimethoxysilane, β-glycidoxy propyl triethoxysilane, β-glycidoxy propyl tripropoxysilane, γ-glycidoxy propyl trimethoxysilane, γ-glycidoxy propyl triethoxysilane, γ-glycidoxy propyl tripropoxysilane, 2-(3,4-epoxycyclohexyl) ethyltrimethoxysilane, 2-(3,4-epoxycyclohexyl) ethyltriethoxysilane.

The invention aims also at manufacturing fluorescent films. In order to deposit semiconductor nanoparticles on substrate, di-electrophoretic forces may be used. Said forces result in attraction of a polarizable object placed in an electric field produced by an electrically polarized surface. In addition, precision of deposition, i.e. definition of limits between areas where semiconductor nanoparticles are deposited and areas where no deposition occurs, is improved.

Semiconductor nanoparticles of the invention are polarizable. Preferably, semiconductor nanoparticles are neutral, i.e. not charged with permanent electric charges. In particular, anisotropic semiconducting nanoparticles are subject to strong di-electrophoretic forces, considering that the physical dependence is proportional to the third power of the bigger dimension of the nanoparticles. Quantum Dots are limited in size by the emission wavelength, but Quantum Plates could be synthetized with longer dimensions (width and length) respect to the thickness (which controls the emission wavelength). To have the desired emission color, the limitation of size is only related to the thickness (quantum confinement), whereas length and width could be left bigger in order to have stronger dielectrophoretic forces (which are proportional to the third power of nanoparticle dimensions).

Therefore, invention also relates to a process for the manufacture of a fluorescent film comprising a substrate and semiconductor nanoparticles distributed on the substrate according to a periodic pattern, wherein the repetition unit of the pattern has a smallest dimension of less than 500 micrometer and comprises at least two pixels comprising the steps of:
i) Providing a substrate;
ii) Creating a surface electric potential on the substrate according to the pattern, so that at least one pixel of the repetition unit is created in the whole pattern; and
iii) Bringing the substrate in contact with a colloidal dispersion of semiconductor nanoparticles for a contacting time of less than 15 minutes, wherein nanoparticles have at least one of a longest dimension greater than 25 nanometers or an aspect ratio greater than 1.5.

In an embodiment, at least one pixel comprises a density of semiconductor nanoparticles per surface unit greater than 5×10⁹ nanoparticles·cm⁻² During semiconductor nanoparticles deposition, substrate needs to be electrically polarized. This polarization may be permanent or induced.

Permanent polarization exists in materials known as electret: after application of an electric field to an electret material, a permanent electrical polarization remains. With electret material, it is possible to write a surface electric potential then to deposit semiconductor nanoparticles. In this case, the substrate is an electret substrate and the surface electric potential is written on the electret substrate.

In this embodiment, the invention also relates to a process for the manufacture of a fluorescent film comprising a substrate and semiconductor nanoparticles distributed on the substrate according to a periodic pattern, wherein the repetition unit of the pattern has a smallest dimension of less than 500 micrometers and comprises at least two pixels comprising the following steps.

In a first step, providing an electret substrate. The substrate may be any embodiment of substrate as defined above in the detailed description of the fluorescent film of the invention. A preferred substrate has an external surface of PMMA, i.e. the substrate is a PMMA film or the substrate is an array of blue LEDs under a film of PMMA.

In a second step, writing a surface electric potential on the electret substrate according to the pattern, so that at least one pixel of the repetition unit is written in the whole pattern.

Then, in a third step, the electret substrate is brought in contact with a colloidal dispersion of semiconductor nanoparticles having at least one of a longest dimension greater than 25 nanometers and/or an aspect ratio greater than 1.5; for a contacting time of less than 15 minutes. Due to polarization density of electret, a di-electrophoretic force is imposed to semiconductor nanoparticles which are thus attracted towards the surface. As semiconductor nanoparticles are larger than 25 nm or anisotropic, attractive forces are significant, yielding an improved deposition of semiconductor nanoparticles: deposit is denser. If semiconductor nanoparticles are anisotropic, they are eventually oriented on the surface along a predetermined direction.

Contact may be done by immersion of electret substrate in a colloidal dispersion of semiconductor nanoparticles, preferably in a colloidal dispersion comprising semiconductor nanoparticles in an organic solvent, more preferably in a hydrocarbon solvent such as cyclohexane, hexane, heptane, decane or pentane.

Alternatively, contact may be done by drop-casting, spin coating, pouring a colloidal dispersion of semiconductor nanoparticles on the substrate, or by micro-fluidic contact system.

Alternatively, contact may be done by spraying micrometric droplets of colloidal dispersion of semiconductor nanoparticles in a flux of gas. Due to electric polarization density of electret, a di-electrophoretic force is imposed to semiconductor nanoparticles. It's worth noting that the solvent is preferably selected in non-polar solvent (such as for example heptane, pentane, hexane, decane), so that no di-electrophoretic forces are imposed to solvent and, moreover, electrical forces are reduced when the dielectric constant of the solvent is big, as in polar solvents. Micrometric droplets are thus attracted towards the surface. At the same time, drying occurs by evaporation of the solvent. As micrometric droplets are bigger than semiconductor nanoparticles, the di-electrophoretic force effect is strongly increased yielding an improved deposition of semiconductor nanoparticles. This method enables coating of large surfaces of substrate and improves homogeneity of deposition. Moreover, with a suitable calibration of the flow rate of the gas, a strong reduction of nanoparticle solution waste and reduction of cleaning processes are obtained.

All features of the fluorescent film of the invention, in particular of semiconductor nanoparticles may be implemented in said process.

In a variant of this embodiment, the invention also relates to a process for the manufacture of a fluorescent film comprising a substrate and semiconductor nanoparticles distributed on the substrate according to a periodic pattern, wherein the repetition unit of the pattern has a smallest dimension of less than 500 micrometers and comprises at least two pixels and wherein semiconductor nanoparticles on the first pixel of the at least two pixels are different from semiconductor nanoparticles on the second pixel of the at least two pixels comprising the following steps.

In a first step, providing an electret substrate. The substrate may be any embodiment of substrate as defined above in the detailed description of the fluorescent film of the invention. A preferred substrate has an external surface of PMMA, i.e. the substrate is a PMMA film or the substrate is an array of blue LEDs under a film of PMMA, or the substrate is an array of blue OLEDs under a film of PMMA.

In a second step, writing a surface electric potential on the electret substrate according to the pattern, so that at least one pixel of the repetition unit is written in the whole pattern.

In a third step, the electret substrate is brought in contact with a colloidal dispersion of semiconductor nanoparticles having at least one of a longest dimension greater than 25 nanometers an aspect ratio greater than 1.5; for a contacting time of less than 15 minutes.

Then, in a fourth step, electret substrate and semiconductor nanoparticles deposited thereon are dried to form an intermediate structure. Said intermediate structure can be treated as an electret substrate in the same manner as above if substrate surface has not been totally covered with semiconductor nanoparticles, i.e. if some surface of the electret substrate is still available to be electrically influenced, said surface is thus available for nanoparticles deposition.

In a fifth step, writing a surface electric potential on the intermediate structure according to the pattern, so that the second pixel of the repetition unit is written in the whole pattern. The surface electric potential is written on parts of the surface on which no nanoparticles have been deposited during steps two to four.

Then, in a sixth step, the electret substrate is brought in contact with a colloidal dispersion of semiconductor nanoparticles having at least one of a longest dimension greater than 25 nanometers an aspect ratio greater than 1.5; for a contacting time of less than 15 minutes.

In some embodiments, steps four to six may be reiterated to yield a third pixel, a fourth pixel, without other limit than the definition of the repetition unit and pixels.

In steps three and six, contact may be done by immersion of electret substrate in a colloidal dispersion of semiconductor nanoparticles or by spraying micrometric droplets as described above.

Alternatively, contact may be done by drop-casting, spin coating, pouring a colloidal dispersion of semiconductor nanoparticles on the substrate, or by micro-fluidic contact system.

All features of the fluorescent film of the invention, in particular of semiconductor nanoparticles may be implemented in said process.

Besides processes using electret substrate having a permanent polarization, other processes use induced polarization. In this case, the induced surface electric potential is maintained during the duration of contact between the substrate and the colloidal dispersion.

Induced polarization corresponds to materials in which electrical polarization results from application of an external electrical field. As soon as external field is removed, electrical polarization disappears. In this case, it is possible to induce a surface electric potential and deposit semiconductor nanoparticles while surface electric potential is maintained.

In this embodiment, the invention relates to a process for the manufacture of a fluorescent film comprising a substrate and semiconductor nanoparticles distributed on the substrate according to a periodic pattern, wherein the repetition unit of the pattern has a smallest dimension of less than 500 micrometers and comprises at least two pixels comprising the following steps.

In a first step, providing a substrate. The substrate may be any embodiment of substrate as defined above in the detailed description of the fluorescent film of the invention.

In a second step, inducing a surface electric potential on the substrate according to the pattern, so that at least one pixel of the repetition unit is induced in the whole pattern.

Then, in a third step, the substrate is brought in contact with a colloidal dispersion of semiconductor nanoparticles having at least one of a longest dimension greater than 25 nanometers an aspect ratio greater than 1.5; for a contacting time of less than 15 minutes, while surface electric potential is maintained. Due to electric polarization density of substrate, a di-electrophoretic force is imposed to semiconductor nanoparticles which are thus attracted towards the surface. If semiconductor nanoparticles are anisotropic, an electro-rotation effect takes place, yielding an improved deposition of semiconductor nanoparticles: deposit is denser, eventually semiconductor nanoparticles are oriented on the surface along a predetermined direction.

Contact may be done by immersion of substrate in a colloidal dispersion of semiconductor nanoparticles, preferably in a colloidal dispersion comprising semiconductor nanoparticles in an organic solvent, more preferably in a hydrocarbon solvent such as cyclohexane, hexane, heptane or pentane.

Alternatively, contact may be done by drop-casting, spin coating, pouring a colloidal dispersion of semiconductor nanoparticles on the substrate, or by micro-fluidic contact system.

Alternatively, contact may be done by spraying micrometric droplets of colloidal dispersion of semiconductor nanoparticles in a flux of gas. Due to electric polarization density of substrate, a di-electrophoretic force is imposed to semiconductor nanoparticles.

It's worth noting that the solvent is preferably selected in non-polar solvent, so that no di-electrophoretic forces are imposed to solvent. Micrometric droplets are thus attracted towards the surface. At the same time, drying occurs by evaporation of the solvent. As micrometric droplets are bigger than single semiconductor nanoparticles, the di-electrophoretic force effect is strongly increased yielding an improved deposition of semiconductor nanoparticles. This method enables coating of large surfaces of substrate and improves homogeneity and speed of deposition. Moreover, with a suitable calibration of the flow rate of the gas, a strong reduction of nanoparticle solution waste and reduction of cleaning processes are obtained.

During third step, one has to simultaneously maintain surface electric potential and bring in contact the substrate with the colloidal suspension. The device used to induce surface electric potential may be located on side of the substrate on which semiconductor nanoparticles are deposited. Alternatively, the device used to induce surface electric potential may be located on the opposite side of the substrate's side on which semiconductor nanoparticles are deposited. This second configuration is preferred as contact between colloidal suspension and device used to induce surface electric potential is avoided. However, this configuration requires that substrate is not too thick: a thickness less than 50 μm, preferably less than 20 μm is preferred and allow improved precision of deposition.

All features of the fluorescent film of the invention, in particular of semiconductor nanoparticles may be implemented in said process.

In a variant of this embodiment, the invention also relates to a process for the manufacture of a fluorescent film comprising a substrate and semiconductor nanoparticles distributed on the substrate according to a periodic pattern, wherein the repetition unit of the pattern has a smallest dimension of less than 500 micrometers and comprises at least two pixels and wherein semiconductor nanoparticles on the first pixel of the at least two pixels are different from semiconductor nanoparticles on the second pixel of the at least two pixels comprising the following steps.

In a first step, providing a substrate. The substrate may be any embodiment of substrate as defined above in the detailed description of the fluorescent film of the invention.

In a second step, inducing a surface electric potential on the substrate according to the pattern, so that the first pixel of the repetition unit is induced in the whole pattern.

In a third step, the substrate is brought in contact with a colloidal dispersion of semiconductor nanoparticles having at least one of a longest dimension greater than 25 nanometers an aspect ratio greater than 1.5; for a contacting time of less than 15 minutes, while surface electric potential is maintained.

Then, in a fourth step, substrate and semiconductor nanoparticles deposited thereon are dried to form an intermediate structure. Said intermediate structure can be treated as a substrate in the same manner as above if substrate surface has not been totally covered with semiconductor nanoparticles, i.e. if some surface of the substrate is still available to be electrically influenced, said surface is thus available for nanoparticles deposition.

In a fifth step, inducing a surface electric potential on the intermediate structure according to the pattern, so that the second pixel of the repetition unit is induced in the whole pattern. The surface electric potential is induced on parts of the surface on which no nanoparticles have been deposited during steps two to four.

In a sixth step, the substrate is brought in contact with a colloidal dispersion of semiconductor nanoparticles having at least one of a longest dimension greater than 25 nanometers an aspect ratio greater than 1.5; and different from those used in third step for a contacting time of less than 15 minutes, while surface electric potential is maintained.

During third and sixth steps, one has to simultaneously maintain surface electric potential and bring in contact substrate with colloidal suspension. The device used to induce surface electric potential may be located on side of the substrate on which semiconductor nanoparticles are deposited. Alternatively, the device used to induce surface electric potential may be located on the opposite side of the substrate's side on which semiconductor nanoparticles are deposited. This second configuration is preferred as contact between colloidal suspension and device used to induce surface electric potential is avoided. However, this configuration requires that substrate is not too thick: a thickness less than 50 μm, preferably less than 20 μm is preferred and allow improved precision of deposition.

In some embodiments, steps four to six may be reiterated to yield a third pixel, a fourth pixel, without other limit than the definition of the repetition unit and pixels.

In steps three and six, contact may be done by immersion of substrate in a colloidal dispersion of semiconductor nanoparticles or by spraying micrometric droplets as described above.

All features of the fluorescent film of the invention, in particular of semiconductor nanoparticles may be implemented in said process.

The invention also relates to a colour conversion layer comprising a fluorescent film comprising a substrate and semiconductor nanoparticles distributed on the substrate according to a periodic pattern, wherein semiconductor nanoparticles have at least one of a longest dimension greater than 25 nanometers an aspect ratio greater than 1.5; wherein the repetition unit of the pattern has a smallest dimension of less than 500 micrometers and comprises at least two pixels. All embodiments of the fluorescent film of the invention may be implemented in said light emitting device. In particular, at least one pixel comprises a density of semiconductor nanoparticles per surface unit greater than 5×10⁹ nanoparticles·cm⁻².

While various embodiments have been described and illustrated, the detailed description is not to be construed as being limited hereto. Various modifications can be made to the embodiments by those skilled in the art without departing from the true spirit and scope of the disclosure as defined by the claims.

### EXAMPLES

The present invention is further illustrated by the following examples.

### Example 1

Preparation of a Stamp:

A photolithographic mask is fabricated on a UV-blue transparent substrate to reproduce a pattern with squared pixels of 5 μm size distributed on a square lattice of period 15 μm. A silicon carrier is covered by a uniform photolithography resin and illuminated by an UV lamp producing a 350 nm light filtered by the lithography mask in order to impress the pattern on the carrier. A proper washing solution for the resin is utilized to develop the polymer and create a tridimensional motif (pixelization).

A PDMS solution is casted on this tridimensional motif and the silicon carrier, then heated at 150° C. for 24 h to assure the polymerization of the PDMS. The solidified PDMS is thus separated from the silicon carrier. The so patterned PDMS is gold covered by evaporation technique to ensure a conductive pixelated surface. The patterned and conductive PDMS substrate is now called the stamp. It consists of a planar conductive surface on which square pixels of 5 μm size and 20 μm height are distributed on a square lattice. The stamp is a square of size 5 cm.

Preparation of Substrate:

A glass transparent square slide of dimensions 5 cm×5 cm and of 2 mm thickness is covered with Indium Tin Oxide (ITO) layer of thickness 200 nm. Then, a 200 nm thick PMMA solid film is formed by spray coating a solution of PMMA (Mw: 10⁶ g·mol⁻¹) 5% in weight in toluene.

Preparation of Nanoparticles Colloidal Dispersions:

A solution A comprising 10⁻⁸ mole·L⁻¹ CdSe_{0.45}S_{0.55}/Cd_{0.30}Zn_{0.70}S/ZnS nanoplatelets in cyclohexane is prepared. These nanoplatelets are 25 nm long, 20 nm wide and 9 nm thick (core: 1.2 nm; first shell: 2 nm; second shell: 2 nm) and fluoresce at 630 nm with FWHM of 20 nm.

A solution B comprising 10⁻⁸ mole·L⁻¹ CdSe_{0.10}S_{0.90}/ZnS/Cd_{0.20}Zn_{0.80}S nanoplatelets in cyclohexane is prepared. These nanoplatelets are 25 nm long, 20 nm wide and 8.5 nm thick (core: 1.5 nm; first shell: 1 nm; second shell: 2.5 nm) and fluoresce at 530 nm with FWHM of 30 nm.

Emission spectra of nanoparticles from solutions A and B are shown on FIG. 4.

Preparation of the Fluorescent Film:

The substrate is put in contact with the stamp in order to create a capacitive system with the PMMA in the middle (between stamp and glass/ITO) as dielectric medium. A voltage of 50 V is applied for 1 minute in order to create permanent electrical polarization in the PMMA layer (electret material) only in correspondence with the pixels of the stamp.

To maintain stable the charges on the electret, humidity level of the environment is kept below 50%.

Substrate with electrically polarized PMMA film is dipped in solution A for 10 seconds then rinsed by a clean solvent and dried by a gentle flux of nitrogen.

Using a microscopic technique of alignment, the stamp is then again placed on the already red pixelated substrate, with pixels of the stamp defining a second pixel on the substrate (different from the red pixel) according to the original periodic patterning chosen.

A voltage of 50 V is applied again for 1 minute in order to create permanent electrical polarization in the PMMA film only in correspondence with the pixels of the stamp, i.e. in correspondence with areas free of nanoparticles.

Substrate with electrically polarized PMMA film is dipped in solution B for 10 seconds then rinsed by a clean solvent and dried by a gentle flux of nitrogen.

Fluorescent Film and Device:

A 25 cm² substrate of glass/ITO/PMMA with square pixels of 5 μm size and two different types (red and green emitting nanoparticles) distributed on a square lattice of period 15 μm is obtained, forming a fluorescent film.

The substrate is then transferred on an array of blue LEDs (as primary light sources) so that blue LEDs are in correspondence with red and green pixels. A UV curable adhesive is used to ensure adhesion between substrate and array of blue LEDs.

### Example 2

Example 1 is reproduced, except that periodic pattern is changed.

In example 2a, pixels are square with 3 μm size and square lattice has a period of 12 μm.

In example 2b, four squared pixels of size 5 μm are defined on a square lattice of period 15 μm, with one red pixel, two green pixels and one blue pixel.

### Example 3-1

Example 1 is reproduced, except that semiconductor nanoparticles are changed.

A solution D comprising 10⁻⁸ mole·L⁻¹ CdSe_{0.45}S_{0.55}/Cd_{0.30}Zn_{0.70}S/ZnS nanoplatelets in cyclohexane is prepared. These nanoplatelets are 35 nm long, 25 nm wide and 10.2 nm thick (core: 1.2 nm; first shell: 2.5 nm; second shell: 2 nm) and fluoresce at 630 nm with FWHM of 25 nm.

After dipping of electrically polarized PMMA film in solution D instead of solution A, nanoparticle deposition is observed as for example 1. It is observed that deposition is obtained in shorter exposure time, namely 4 seconds instead of 10 seconds.

### Example 3-2

Example 1 is reproduced, except that semiconductor nanoparticles are changed.

TABLE I
Colloidal dispersions of semiconductor nanoparticles used for deposition on substrate.
(MLs refers to the number of monolayers of inorganic material covering the core).

| | Dimensions | | | | | | |
|---|---|---|---|---|---|---|---|
| | L | W | T | [NPs] | Emission | | |
| Nanoparticles (NPs) | (nm) | (nm) | (nm) | (mol · L⁻¹) | peak | FWHM | Deposition |

CORE/SHELL NANOPLATELETS

| | | | | | | | |
|---|---|---|---|---|---|---|---|
| CdS/ZnS 5 MLs | 17 | 17 | 3.2 | 5 × 10⁻⁶ | 465 nm | 14 nm | observed |
| CdS/ZnSe_{0.5}S_{0.5} 5 MLs | 15 | 15 | 3.2 | 2 × 10⁻⁶ | 465 nm | 15 nm | observed |
| CdS/ZnSe 5 MLs | 17 | 17 | 3.5 | 1 × 10⁻⁶ | 460 nm | 15 nm | observed |
| CdSe_{0.30}S_{0.70}/ZnS 5 MLs | 25 | 20 | 3.1 | 0.2 × 10⁻⁶ | 535 nm | 28 nm | observed |
| CdSe_{0.25}S_{0.75}/Cd_{0.05}Zn_{0.95}S | 27 | 22 | 3.4 | 2 × 10⁻⁶ | 550 nm | 30 nm | observed |
| CdSe_{0.20}S_{0.80}/ZnSe 5 MLs | 24 | 18 | 3.0 | 2 × 10⁻⁶ | 540 nm | 29 nm | observed |
| CdSe_{0.20}S_{0.80}/ZnSe_{0.50}S_{0.50} | 26 | 20 | 3.3 | 0.5 × 10⁻⁶ | 530 nm | 30 nm | observed |
| 5 MLs | | | | | | | |
| CdSe_{0.83}S_{0.17}/Cd_{0.50}Zn_{0.50}S | 28 | 18 | 5 | 1 × 10⁻⁶ | 621 nm | 29 nm | observed |
| 4 MLs | | | | | | | |
| CdSe/Cd_{0.1}Zn_{0.9}S 4 MLs | 16 | 17 | 4.9 | 2 × 10⁻⁶ | 625 nm | 22 nm | observed |
| CdSe_{0.75}S_{0.25}/Cd_{0.50}Zn_{0.50}S | 30 | 20 | 4.8 | 4 × 10⁻⁶ | 645 nm | 26 nm | observed |
| 4 MLs | | | | | | | |
| CdSe/ZnSe_{0.50}S_{0.50} 4 MLs | 17 | 17 | 4 | 2 × 10⁻⁶ | 645 nm | 28 nm | observed |
| CdSe/ZnS 4 MLs | 17 | 17 | 4 | 3.5 × 10⁻⁶ | 617 nm | 27 nm | observed |

CORE/SHELL/SHELL NANOPLATELETS

| | | | | | | | |
|---|---|---|---|---|---|---|---|
| ZnSe/ZnSe_{0.4}S_{0.6}/ZnS | 50 | 20 | 3.2 | 20 × 10⁻⁶ | 445 nm | 15 nm | observed |
| CdSe_{0.90}S_{0.10}/ZnSe/ZnS | 27 | 19 | 5 | 2 × 10⁻⁶ | 650 nm | 28 nm | observed |
| 4 MLs | | | | | | | |

CORE/CROWN NANOPLATELETS

| | | | | | | | |
|---|---|---|---|---|---|---|---|
| CdSe/CdS 3 MLs | 20 | 12 | 0.9 | 3 × 10⁻⁶ | 465 nm | 10 nm | observed |
| CdS/ZnSe 5 MLs | 15 | 15 | 1.2 | 2 × 10⁻⁶ | 468 nm | 15 nm | observed |
| CdSe/CdS 4 MLs | 15 | 15 | 1.2 | 2 × 10⁻⁶ | 515 nm | 10 nm | observed |
| CdSe_{0.90}S_{0.10}/CdS 5 MLs | 27 | 21 | 1.5 | 2.5 × 10⁻⁶ | 540 nm | 14 nm | observed |
| CdSe/CdS 5 MLs | 26 | 17 | 1.5 | 1 × 10⁻⁶ | 555 nm | 12 nm | observed |

DOT IN PLATE NANOPLATELETS (core: quantum dot, final nanoparticle: nanoplatelet)

| | | | | | | | |
|---|---|---|---|---|---|---|---|
| CdSe/CdS 3 MLs | 15 | 15 | 0.9 | 2.3 × 10⁻⁶ | 462 nm | 10 nm | observed |
| CdSe_{0.50}S_{0.50}/CdS/ZnS | 25 | 25 | 3.2 | 2 × 10⁻⁶ | 540 nm | 35 nm | observed |
| 4 MLs | | | | | | | |

CORE/CROWN/SHELL NANOPLATELETS

| | | | | | | | |
|---|---|---|---|---|---|---|---|
| CdS/ZnSe/ZnS 5 MLs | 17 | 17 | 3.5 | 2 × 10⁻⁶ | 550 nm | 30 nm | observed |
| CdSe_{0.30}S_{0.70}/CdS/ZnS | 27 | 20 | 3.4 | 10 × 10⁻⁶ | 550 nm | 30 nm | observed |
| 5 MLs | | | | | | | |

After dipping of substrate with electrically polarized PMMA layer in a colloidal dispersion of semiconductor nanoparticles listed in Table I instead of solution A, nanoparticle deposition is observed as for example 1.

### Example 4

Example 1 is reproduced, except that composite nanoparticles comprising fluorescent semiconductor nanoparticles encapsulated in a matrix are used.

### Example 4-1: Fluorescent Nanoplatelets in SiO₂ Matrix

First, 500 μL of colloidal CdSe_{0.45}S_{0.55}/Cd_{0.30}Zn_{0.70}S/ZnS nanoplatelets in abasic aqueous solution is prepared. These nanoplatelets are 25 nm long, 20 nm wide and 9 nm thick (core: 1.2 nm; first shell: 2 nm; second shell: 2 nm) and fluoresce at 630 nm with FWHM of 20 nm. 10 μL of a hydrolyzed basic aqueous solution of tetraethylorthosilicate (TEOS) at 0.13 mole·L⁻¹ is added to colloidal nanoplatelets and gently mixed. The liquid mixture is sprayed towards a tube furnace heated at a temperature of 300° C. with a nitrogen flow. Composite nanoparticles are collected at the surface of a filter, with diameters from 25 to 200 nm.

A solution E comprising 10⁻⁶ mole·L⁻¹ CdSe_{0.45}S_{0.55}/Cd_{0.30}Zn_{0.70}S/ZnS of composite nanoparticles in heptane is prepared.

### Example 4-2: Fluorescent Nanoplatelets in Al₂O₃ Matrix

First, 500 μL of colloidal CdSe_{0.45}S_{0.55}/Cd_{0.30}Zn_{0.70}S/ZnS nanoplatelets in heptane is prepared. These nanoplatelets are 25 nm long, 20 nm wide and 9 nm thick (core: 1.2 nm; first shell: 2 nm; second shell: 2 nm) and fluoresce at 630 nm with FWHM of 20 nm. 5 mL of a solution of aluminium tri-sec butoxide at 0.25 mole·L⁻¹ in heptane is added to colloidal nanoplatelets and gently mixed. A basic aqueous solution is prepared separately. The two liquids are sprayed simultaneously towards a tube furnace heated at a temperature of 300° C. with a nitrogen flow. Composite nanoparticles are collected at the surface of a filter, with diameters from 25 to 200 nm.

A solution F comprising 10⁻⁶ mole·L⁻¹ CdSe_{0.45}S_{0.55}/Cd_{0.30}Zn_{0.70}S/ZnS of composite nanoparticles in heptane is prepared.

### Example 4-3: Fluorescent Nanoplatelets in Organic Matrix

First, 500 μL of colloidal CdSe_{0.45}S_{0.55}/Cd_{0.30}Zn_{0.70}S/ZnS nanoplatelets in heptane is prepared. These nanoplatelets are 25 nm long, 20 nm wide and 9 nm thick (core: 1.2 nm; first shell: 2 nm; second shell: 2 nm) and fluoresce at 630 nm with FWHM of 20 nm. 200 mg of PMMA (PolyMethylMethAcrylate, 120 kDa) is solubilized in 10 mL of toluene, then mixed with colloidal solution. The liquid mixture was sprayed towards a tube furnace heated at 200° C. with a nitrogen flow. Composite nanoparticles are collected at the surface of a filter, with diameters from 25 to 200 nm.

A solution G comprising 10⁻⁶ mole·L⁻¹ CdSe_{0.45}S_{0.55}/Cd_{0.30}Zn_{0.70}S/ZnS of composite nanoparticles in heptane is prepared.

### Example 4-4: Fluorescent Nanoparticles in Al₂O₃ Matrix

First, 4 mL InP/ZnSe_{0.50}S_{0.50}/ZnS nanoparticles in heptane is prepared. These nanoparticles have a diameter of 9.5 nm (core of diameter: 3.5 nm; first shell thickness: 2 nm; second shell thickness: 1 nm) and fluoresce at 630 nm with FWHM of 45 nm. 5 mL of a solution of aluminium tri-sec butoxide at 0.25 mole·L⁻¹ is added to colloidal nanoplatelets and gently mixed. A basic aqueous solution is prepared separately. The two liquids are sprayed simultaneously towards a tube furnace heated at a temperature of 300° C. with a nitrogen flow. Composite nanoparticles are collected at the surface of a filter, with diameters from 25 to 200 nm.

A solution of 50 mg of composite nanoparticles in 9 mL of tetrahydrofuran is prepared. 13 μL of octanoic acid, 60 μL of a 4-(dimethylamino)pyridine stock solution (1 mg/100 μL of dimethylformamide), 6 μL of triethylamine and 2 μL of benzoyl chloride are added. The mixture is then left to mix at room temperature over 48 hours, yielding composite nanoparticles with surface modification allowing for better dispersion in hydrocarbons solvents.

A solution H-1 comprising 10⁻⁶ mole·L⁻¹ InP/ZnSe_{0.50}S_{0.50}/ZnS of composite nanoparticles in heptane is prepared.

A solution H-2 is prepared similarly with InP/ZnSe_{0.50}S_{0.50} nanocrystals having a diameter of 7.5 nm (core of diameter: 2.5 nm; shell thickness: 2 nm) and emitting green light at 535 nm with FWHM of 40 nm.

### Example 4-5: Fluorescent Nanoparticles in Organic Matrix

First, 100 μL of InP/ZnSe_{0.50}S_{0.50}/ZnS nanoparticles in heptane is prepared. These nanoparticles have a diameter of 9.5 nm (core of diameter: 3.5 nm; first shell thickness: 2 nm; second shell thickness: 1 nm) and fluoresce at 630 nm with FWHM of 45 nm. 200 mg of PMMA (PolyMethylMethAcrylate, 120 kDa) is solubilized in 10 mL of toluene, then mixed with colloidal solution. The liquid mixture was sprayed towards a tube furnace heated at 200° C. with a nitrogen flow. Composite nanoparticles are collected at the surface of a filter, with diameters from 25 to 200 nm.

A solution I-1 comprising 10⁻⁶ mole·L⁻¹ InP/ZnSe_{0.50}S_{0.50}/ZnS of composite nanoparticles in heptane is prepared.

A solution I-2 is prepared similarly with InP/ZnSe_{0.50}S_{0.50} nanocrystals having a diameter of 7.5 nm (core of diameter: 2.5 nm; shell thickness: 2 nm) and emitting green light at 535 nm with FWHM of 40 nm.

After dipping of electrically polarized PMMA film in solution E, F, G, H-1, H-2, I-1 or I-2 instead of solution A, composite nanoparticle deposition is observed as for example 1, but thickness of layer of composite nanoparticles deposited is larger than thickness of layer of non-encapsulated nanoparticles.

### Example 4-6: Composite Particles Comprising Fluorescent Semiconductor Nanoparticles in Matrix

Example 1 is reproduced with composite nanoparticles comprising fluorescent nanoparticles encapsulated in a matrix listed in Table II.

TABLE II
Colloidal dispersions of composite particles used for deposition on electret film.

| | | | | |
|---|---|---|---|---|
| | | | Composite | |
| | | | particle | Film fluorescence |
| Nanoparticles | dimensions | Matrix | dimensions (nm) | (nm) |

QUANTUM DOTS IN MATRIX

| | | | | | |
|---|---|---|---|---|---|
| InP/ZnSe_{0.50}S_{0.50}/ZnS | 7.2 | nm | Al₂O₃ | 200 | 510 |
| InP/GaP | 5 | nm | SiO₂ | 500 | 510 |
| Cd₃P₂ | 2 | nm | PMMA | 450 | 507 |
| Cd_{0.20}Zn_{0.80}Se/ZnSe/ZnS | 15 | nm | Al₂O₃ | 150 | 597 |
| CdSe/Zn_{0.50}Cd_{0.50}Se/ZnSe | 7 | nm | SiO₂ | 350 | 608 |

NANOPLATELETS IN MATRIX (L*W*T)

| | | | | | |
|---|---|---|---|---|---|
| CdSe_{0.40}S_{0.60} 5 MLs | 27*18*1.5 | nm | Al₂O₃ | 200 | 505 |
| CdSe 4 MLs | 8*4*1.2 | nm | SiO₂ | 500 | 514 |
| CdSe 8 MLs | 50*9*2.4 | nm | PMMA | 350 | 625 |
| CdSe_{0.40}S_{0.60} 5 MLs | 27*18*1.5 | nm | Al₂O₃ | 250 | 505 |

CORE/SHELL NANOPLATELETS

| | | | | |
|---|---|---|---|---|
| CdS/ZnS 5 MLs | 17*17*3.2 | Al₂O₃ | 200 | 465 |
| CdS/ZnSe_{0.5}S_{0.5} 5 MLs | 15*15*3.2 | SiO₂ | 500 | 465 |
| CdS/ZnSe 5 MLs | 17*17*3.5 | PMMA | 350 | 460 |
| CdSe_{0.30}S_{0.70}/ZnS 5 MLs | 25*20*3.1 | Al₂O₃ | 250 | 535 |
| CdSe_{0.25}S_{0.75}/Cd_{0.05}Zn_{0.95}S | 27*22*3.4 | Al₂O₃ | 175 | 550 |
| CdSe_{0.20}S_{0.80}/ZnSe 5 MLs | 24*18*3.0 | SiO₂ | 325 | 540 |
| CdSe_{0.20}S_{0.80}/ZnSe_{0.50}S_{0.50} | 26*20*3.3 | PMMA | 400 | 530 |
| 5 MLs | | | | |
| CdSe_{0.83}S_{0.17}/Cd_{0.50}Zn_{0.50}S | 28*18*5 | SiO₂ | 250 | 621 |
| 4 MLs | | | | |
| CdSe/Cd_{0.1}Zn_{0.9}S 4 MLs | 16*17*4.9 | PMMA | 280 | 625 |
| CdSe_{0.75}S_{0.25}/Cd_{0.50}Zn_{0.50}S | 30*20*4.8 | SiO₂ | 420 | 645 |
| 4 MLs | | | | |
| CdSe/ZnSe_{0.50}S_{0.50} 4 MLs | 17*17*4 | PMMA | 450 | 645 |
| CdSe/ZnS 4 MLs | 17*17*4 | Al₂O₃ | 190 | 617 |

CORE/SHELL/SHELL NANOPLATELETS

| | | | | |
|---|---|---|---|---|
| ZnSe/ZnSe_{0.5}S_{0.5}/ZnS | 50*20*3.2 | Al₂O₃ | 220 | 445 |
| CdSe_{0.90}S_{0.10}/ZnSe/ZnS | 27*19*5 | SiO₂ | 410 | 650 |
| 4 MLs | | | | |

CORE/CROWN NANOPLATELETS

| | | | | |
|---|---|---|---|---|
| CdSe/CdS 3 MLs | 20*12*0.9 | SiO₂ | 360 | 465 |
| CdS/ZnSe 5 MLs | 15*15*1.2 | PMMA | 325 | 468 |
| CdSe/CdS 4 MLs | 15*15*1.2 | SiO₂ | 275 | 515 |
| CdSe_{0.90}S_{0.10}/CdS 5 MLs | 27*21*1.5 | Al₂O₃ | 290 | 540 |
| CdSe/CdS 5 MLs | 26*17*1.5 | SiO₂ | 340 | 555 |

DOT IN PLATE NANOPLATELETS (core: quantum dot, final nanoparticle: nanoplatelet)

| | | | | |
|---|---|---|---|---|
| CdSe/CdS 3 MLs | 15*15*0.9 | PMMA | 250 | 462 |
| CdSe_{0.50}S_{0.50}/CdS/ZnS | 25*25*3.2 | SiO₂ | 150 | 540 |
| 4 MLs | | | | |

CORE/CROWN/SHELL NANOPLATELETS

| | | | | |
|---|---|---|---|---|
| CdS/ZnSe/ZnS 5 MLs | 17*17*3.5 | SiO₂ | 245 | 550 |
| CdSe_{0.30}S_{0.70}/CdS/ZnS | 27*20*3.4 | PMMA | 350 | 550 |
| 5 MLs | | | | |

### Example 5

Example 1 is reproduced, but adapted to large dimensions of fluorescent film and device.

Preparation of a Stamp:

Pixels are square of 100 μm size and square lattice has a period of 500 μm. The stamp obtained consists of a planar conductive surface on which square pixels of 100 μm size and 200 μm heights are distributed on a square lattice. The stamp is a 300 mm diameter disc.

Preparation of Substrate:

A glass transparent rectangular slide of dimensions 100 cm×200 cm and of 2 mm thickness is covered with Indium Tin Oxide (ITO) layer of thickness 200 nm. Then, a 200 nm thick PMMA solid film is formed by spray coating a solution of PMMA (Mw: 10⁶ g·mol⁻¹) 5% in weight in toluene.

Preparation of Fluorescent Film:

A part of the glass substrate is put in contact with the stamp in order to create a capacitive system with the PMMA in the middle (between stamp and glass/ITO) as dielectric medium. A voltage of 50 V is applied for 1 minute in order to create permanent electrical polarization in the PMMA layer (electret material) only in correspondence with the pixels of the stamp. The stamp is then moved in other positions in order to completely cover all the large glass surface and obtain a permanent electrical polarization in all the PMMA surface.

The substrate with electrically polarized PMMA layer is entirely covered by dropping the solution A of nanoparticles for 10 seconds over all the surface. The substrate is then rinsed by a clean solvent and dried by a gentle flux of nitrogen.

Both operations are repeated with solution B.

Both operations are repeated with a solution C comprising Al₂O₃ nanoparticles of size 500 nm. These nanoparticles will behave as light scatterers.

Finally, a 2 m² glass substrate with square pixels of 100 μm size and three different types (red, green emitting nanoparticles and light scattering zones) distributed on a square lattice of period 500 μm is obtained.

Below the substrate, all necessary other layers and electrical contacts needed for the preparation of primary light source, here a blue LED, in correspondence with each pixel are built by well know techniques in the display industry, yielding a colour conversion layer.

### Example 6

Example 5 is reproduced, but using composite nanoparticles of example 4-4 (solutions H-1 or H-2) and example 4-5 (solutions I-1 or I-2)

### Example 7

Example 1 is reproduced, except that substrate and preparation of fluorescent film are changed.

Substrate is a 50 μm thick square glass slide of size 5 cm. Substrate is held horizontally.

The stamp is placed below the substrate and in contact with the substrate. A voltage of 50 V is applied in order to induce electrical polarization in the substrate only in correspondence with the pixels of the stamp.

While voltage is applied, a layer of solution A is poured on the top side of substrate and voltage is maintained for 10 seconds then shut off. Stamp is removed from bottom side of substrate and excess solution A is removed. Substrate is then rinsed by a clean solvent and dried by a gentle flux of nitrogen.

Using a microscopic technique of alignment, the stamp is then again placed below the already red pixelated substrate, with pixels of the stamp defining a second pixel on the substrate (different from the red pixel) according to the original periodic patterning chosen. A voltage of 50 V is applied in order to induce electrical polarization in correspondence with the pixels of the stamp.

While voltage is applied, a layer of solution B is poured on the top side of substrate and voltage is maintained for 10 seconds then shut off. Stamp is removed from bottom side of substrate and excess solution B is removed. Substrate is then rinsed by a clean solvent and dried by a gentle flux of nitrogen.

Using the same microscopic technique of alignment, the stamp is then again placed below the already red/green pixelated substrate, with pixels of the stamp defining a third pixel on the substrate (different from the red and green pixels) according to the original periodic patterning chosen. A voltage of 50 V is applied in order to induce electrical polarization in correspondence with the pixels of the stamp.

While voltage is applied, a layer of solution C is poured on the top side of substrate and voltage is maintained for 10 seconds then shut off. Stamp is removed from bottom side of substrate and excess solution C is removed. Substrate is then rinsed by a clean solvent and dried by a gentle flux of nitrogen.

### Example 8

Example 7 is reproduced, but using composite nanoparticles of example 4-4 (solutions H-1 or H-2) and example 4-5 (solutions I-1 or I-2)

### Comparative Example C1

Example 1 is reproduced, except that semiconductor nanoparticles are changed.

A solution C-A comprising 10⁻⁸ mole·L⁻¹ CdSe/CdS/ZnS nanoparticles in cyclohexane is prepared. These nanoparticles are spherical (aspect ratio of 1) with a diameter of 6 nm and emit at 620 nm with FWHM of 45 nm.

A solution C-B comprising 10⁻⁸ mole·L⁻¹ Cd_{0.10}Zn_{0.90}Se_{0.10}S_{0.90}/ZnS nanoparticles in cyclohexane is prepared. These nanoparticles are spherical (aspect ratio of 1) with a diameter of 6 nm and emit at 540 nm with FWHM of 37 nm.

After dipping of substrate with electrically polarized PMMA layer in solution C-A, nanoparticle deposition results in a non homogeneous monolayer of nanoparticles deposited on the substrate. This is not sufficient to achieve satisfying film fluorescence with good conversion ratio.

After dipping of substrate with electrically polarized PMMA layer in solution C-B, nanoparticle deposition results in a non homogeneous monolayer of nanoparticles deposited on the substrate. This is not sufficient to achieve satisfying film fluorescence.

Even if nanoparticles of solutions C-A and C-B have a larger volume than nanoparticles of example 1, they are isotropic (spheres) with aspect ratio of 1 and form too thin deposits on substrate to achieve sufficient film fluorescence.

In addition, spherical nanoparticles emitting light in shorter wavelength, typically in blue range, are even smaller in diameter.

### Comparative Example C2

Example 1 is reproduced, except that semiconductor nanoparticles are changed.

A solution C-C comprising 10⁻⁸ mole·L⁻¹ CdSe/CdS/ZnS nanoparticles in cyclohexane is prepared. These nanoparticles are spherical (aspect ratio of 1) with a diameter of 3 nm and emit at 620 nm with FWHM of 45 nm.

A solution C-D comprising 10⁻⁸ mole·L⁻¹ Cd_{0.10}Zn_{0.90}Se_{0.10}S_{0.90}/ZnS nanoparticles in cyclohexane is prepared. These nanoparticles are spherical (aspect ratio of 1) with a diameter of 4 nm and emit at 540 nm with FWHM of 37 nm.

After dipping of substrate with electrically polarized PMMA layer in solution C-C instead of A, a monolayer of nanoparticles is observed to have been deposited on the substrate. This is not sufficient to achieve satisfying film fluorescence.

After dipping of substrate with electrically polarized PMMA layer in solution C-D instead of B, the layer of nanoparticles deposited on the substrate is too thin to achieve satisfying fluorescence.

Thus, nanoparticles of solutions C-C and C-D do not achieve fluorescent films when deposited on substrate.

1. A fluorescent film comprising a substrate and semiconductor nanoparticles distributed on the substrate according to a periodic pattern, wherein semiconductor nanoparticles have at least one of a longest dimension greater than 25 nanometers or an aspect ratio greater than 1.5; wherein the repetition unit of the pattern has a smallest dimension of less than 500 micrometers and comprises at least two pixels.

2. The fluorescent film according to claim 1, wherein at least one pixel comprises a density of semiconductor nanoparticles per surface unit greater than 5×10⁹ nanoparticles·cm⁻².

3. The fluorescent film according to claim 1, wherein semiconductor nanoparticles are deposited on at least one substrate with a thickness of less than 10000 nm and more than 100 nm, and the volume fraction of semiconductor nanoparticles in said at least one pixel is ranging from 10% to 90%.

4. The fluorescent film according to claim 1, wherein the pattern is periodic in two dimensions.

5. The fluorescent film according to claim 1, wherein semiconductor nanoparticles are inorganic.

6. The fluorescent film according to claim 5, wherein semiconductor nanoparticles are semiconductor nanocrystals comprising a material of formula MₓQ_{y}E_{z}A_{w}, wherein: M is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs or a mixture thereof; Q is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs or a mixture thereof; E is selected from the group consisting of O, S, Se, Te, C, N, P, As, Sb, F, Cl, Br, I, or a mixture thereof; A is selected from the group consisting of O, S, Se, Te, C, N, P, As, Sb, F, Cl, Br, I, or a mixture thereof; and x, y, z and w are independently a rational number from 0 to 5; x, y, z and w are not simultaneously equal to 0; x and y are not simultaneously equal to 0; z and w are not simultaneously equal to 0.

7. The fluorescent film according to claim 1, wherein semiconductor nanoparticles have a longest dimension greater than 25 nanometers and an aspect ratio greater than 1.5.

8. The fluorescent film according to claim 1, wherein semiconductor nanoparticles have an aspect ratio greater than 1.5 and are on the substrate with their longest dimension substantially aligned in a predetermined direction.

9. The fluorescent film according to claim 1, wherein semiconductor nanoparticles are on two of the at least two pixels and semiconductor nanoparticles on the first pixel of the at least two pixels are different from semiconductor nanoparticles on the second pixel of the at least two pixels.

10. The fluorescent film according to claim 1, wherein substrate comprises a primary light source.

11. The fluorescent film according to claim 1, wherein nanoparticles are deposited with a thickness of less than 3000 nm and more than 200 nm.

12. The fluorescent film according to claim 1, wherein semiconductor nanoparticles are composite nanoparticles comprising fluorescent semiconductor nanoparticles encapsulated in a matrix.

13. A colour conversion layer comprising a fluorescent film comprising a substrate and semiconductor nanoparticles distributed on the substrate according to a periodic pattern, wherein semiconductor nanoparticles have at least one of a longest dimension greater than 25 nanometers or an aspect ratio greater than 1.5; wherein the repetition unit of the pattern has a smallest dimension of less than 500 micrometers and comprises at least two pixels.

14. The colour conversion layer according to claim 13, wherein at least one pixel comprises a density of semiconductor nanoparticles per surface unit greater than 5×10⁹ nanoparticles·cm⁻².

15. A process for the manufacture of a fluorescent film comprising a substrate and semiconductor nanoparticles distributed on the substrate according to a periodic pattern, wherein the repetition unit of the pattern has a smallest dimension of less than 500 micrometers and comprises at least two pixels comprising the steps of:
i) providing a substrate;
ii) creating a surface electric potential on the substrate according to the pattern, so that at least one pixel of the repetition unit is created in the whole pattern; and
iii) bringing the substrate in contact for a contacting time of less than 15 minutes with a colloidal dispersion of semiconductor nanoparticles having at least one of a longest dimension greater than 25 nanometers or an aspect ratio greater than 1.5;
wherein surface electric potential is either written on an electret substrate or induced and maintained on the substrate during contact with colloidal dispersion.

16. The process for the manufacture of a fluorescent film according to claim 15, wherein the substrate is an electret substrate and wherein the surface electric potential is written on the electret substrate.

17. The process for the manufacture of a fluorescent film according to claim 15, wherein the surface electric potential is induced and maintained on the substrate during contact with colloidal dispersion.

18. The process for the manufacture of a fluorescent film according to claim 15, wherein at least one pixel comprises a density of semiconductor nanoparticles per surface unit greater than 5×10⁹ nanoparticles·cm⁻².
